(19) United States
(12) Patent Application Publication
(10) Pub. No.: US 2025/0125165 A1
(43) Pub. Date: Apr. 17, 2025

(54) APPARATUSES FOR RADIATIVE HEATING OF AN EDGE REGION OF A SEMICONDUCTOR WAFER

(71) Applicant: Lam Research Corporation, Fremont, CA (US)

(72) Inventors: Sivananda Krishnan Kanakasabapathy, Pleasanton, CA (US); Jeremy Todd Tucker, Redwood City, CA (US); Seng Ong, Newark, CA (US); Jerome S. Hubacek, Fremont, CA (US)

(21) Appl. No.: 18/684,643

(22) PCT Filed: Aug. 16, 2022
(86) PCT No.: PCT/US2022/075035

§ 371 Date: Feb. 16, 2024

Related U.S. Application Data
(60) Provisional application No. 63/260,380, filed on Aug. 18, 2021.

(51) Int. Cl. H01L 21/67; H01L 21/687

(52) U.S. Cl. CPC H01L 21/67115; H01L 21/67103; H01L 21/68735; H01L 21/68785

(57) ABSTRACT

Provided herein are various apparatuses and systems for providing edge heating of semiconductor wafers using optical means. Such systems may direct radiant energy towards the edge region of a semiconductor wafer.

### CROSS REFERENCE TO RELATED APPLICATION

An Application Data Sheet is filed concurrently with this specification as part of the present application. Each application that the present application claims benefit of or priority to as identified in the concurrently filed Application Data Sheet is incorporated by reference herein in its entirety and for all purposes.

### BACKGROUND

During deposition in a processing chamber, film can be deposited not only on a frontside of a wafer, but also on a backside of the wafer. For example, during deposition that uses a condensation process, process gases may condense to form particles that are deposited on the frontside and on an exposed backside of the wafer. This backside deposition can cause various adverse effects to the wafer and other wafers. However, removing this backside deposition is challenging to implement and existing solutions may result in numerous disadvantages to wafers.

The background description provided herein is for the purposes of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

### SUMMARY

Details of one or more implementations of the subject matter described in this specification are set forth in the accompanying drawings and the description below. Other features, aspects, and advantages will become apparent from the description, the drawings, and the claims. The following, non-limiting implementations are considered part of the disclosure; other implementations will be evident from the entirety of this disclosure and the accompanying drawings as well.

In some implementations, a substrate support for semiconductor processing may be provided. The substrate support may include a base plate with a wafer support area on a top of the base plate, the wafer support area having an outer boundary that extends around a center axis of the base plate and being configured to support a wafer. The substrate support may also include an optical wafer edge heating unit having one or more light sources and one or more light emission surfaces, wherein the one or more light emission surfaces may encircle the outer boundary when viewed along the center axis, may be positioned radially outwards from the outer boundary when viewed along the center axis, may be positioned radially offset below the outer boundary by an offset distance when viewed along an axis perpendicular to the center axis, and may direct light in a direction having a directional component that is parallel to the center axis.

In some implementations, the one or more light sources may be a plurality of light emitting diodes, and each light emission surface may be a part of a corresponding light emitting diode.

In some implementations, the light emitting diodes may be vertical-cavity surface-emitting lasers (VCSEL).

In some implementations, the plurality of light emitting diodes may include less than about 300 light emitting diodes.

In some implementations, each light emitting diode may be configured to emit light with wavelengths less than or equal to 1,300 nanometers (nm).

In some implementations, at least one of the one or more light emission surfaces may be oriented at a non-parallel angle with respect to the center axis.

In some implementations, the one or more light sources may be a laser emission source, and each light emission surface may be a part of lens connected via fiberoptic cable to the laser emission source.

In some such implementations, each laser emission source may be configured to emit light with wavelengths less than or equal to 1,300 nanometers (nm).

In some implementations, at least one of the one or more light emission surfaces may be oriented at a non-parallel angle with respect to the center axis.

In some implementations, the wafer may have a wafer outer diameter, and the outer boundary of the wafer support area may be smaller than the wafer outer diameter.

In some implementations, the wafer support may further include one or more windows comprising a material transparent to light emitted by the one or more light sources. The one or more windows may be positioned above the one or more light emission surfaces such that light from the one or more light emission surfaces passes through the one or more windows, and positioned along the center axis between the wafer support area and the one or more light emission surfaces.

In some such implementations, the substrate support may include a plurality of windows.

In some implementations, each window may correspond to each one of the one or more light emission surfaces.

In some implementations, the substrate support may include only one window.

In some implementations, the material may be quartz or sapphire.

In some implementations, the substrate support may further include an active cooling unit that includes one or more coolant channels and a circumferential cooling fin thermally connected to the one or more coolant channels. The circumferential cooling fin may extend around the center axis, may be positioned radially inwards from the one or more light emission surfaces, and may be positioned from the outer boundary by a radial distance of less than or equal to 4 mm.

In some implementations, the substrate support may further include a wafer heating unit positioned within the base plate and having one or more heating zones configured to heat a wafer on the wafer support area. The one or more light emission surfaces may be radially offset from and encircle the one or more heating zones, and the circumferential cooling fin may extend around the one or more heating zones when viewed along the center axis and may be radially interposed between the one or more heating zones and the one or more light emission surfaces when viewed along the center axis.

In some implementations, the wafer support may further include a thermal insulator radially interposed between the circumferential cooling fin and the one or more heating zones.

In some implementations, the circumferential cooling fin may have a radial thickness less than or equal to about 4 mm.

In some implementations, the circumferential cooling fin may have a radial thickness that is at least partially defined by an inner radius and an outer radius, and the inner radius may be less than or equal to about 4 mm from the outer boundary of the wafer support area.

In some implementations, the circumferential cooling fin may be thermally connected to the outer boundary of the wafer support area.

In some implementations, the coolant channels may be positioned along the center axis between the outer boundary and the one or more light emission surfaces, the coolant channels may be positioned within a portion of the base plate, one or more ports may extend through the portion of the base plate, and the one or more light emission surfaces may be connected to the one or more ports such that light from the one or more light emission surfaces passes through the one or more ports to reach the wafer.

In some implementations, the one or more light emission surfaces may be positioned along the center axis between the outer boundary and the coolant channels.

In some implementations, the wafer support may further include a thermal insulator positioned radially inwards of the circumferential cooling fin and the one or more light emission surfaces.

In some implementations, the offset distance may be non-zero and less than or equal to 10 mm.

In some implementations, the one or more light sources may be configured to emit white light.

In some implementations, the one or more light sources may be configured to emit light through the one or more light emission surfaces and heat an edge region of the wafer to a temperature of at least 80° C.

In some implementations, the edge region of the wafer may have a radial thickness of less than or equal to 3.5 mm.

In some implementations, the temperature may be at least 100° C.

In some implementations, the substrate support may be an electrostatic chuck.

In some implementations, an apparatus may be provided that includes a processing chamber defining a chamber interior. The apparatus may further include a substrate support that includes a base plate with a wafer support area on a top of the base plate, the wafer support area having an outer boundary that extends around a center axis of the base plate and configured to support a wafer. The apparatus may further include an optical wafer edge heating unit having one or more light sources and a one or more light emission surfaces. The one or more light emission surfaces may encircle the outer boundary when viewed parallel to the center axis, may be positioned radially outwards from the outer boundary when viewed along the center axis, may be positioned radially offset below the outer boundary by an offset distance when viewed along an axis perpendicular to the center axis, and may direct light in at a direction parallel to the center axis. The apparatus may further include a substrate heating unit positioned within the base plate and having one or more heating zones configured to heat a wafer on the wafer support area. The one or more light emission surfaces may be radially offset from, and encircle, the one or more heating zones.

In some implementations, the apparatus may further include a controller with instructions that are configured to cause the substrate heating unit to maintain a wafer positioned on the wafer support area at a first temperature, and cause, while concurrently maintaining the wafer at the first temperature, the optical wafer edge heating unit to maintain an edge region of the wafer at a second temperature higher than the first temperature.

In some implementations, the first temperature may be between about 20° C. and about 120° C., and the second temperature may be between about 40° C. and about 150° C.

### BRIEF DESCRIPTION OF THE DRAWINGS

The various implementations disclosed herein are illustrated by way of example, and not by way of limitation, in the figures of the accompanying drawings, in which like reference numerals refer to similar elements.

FIG. 1A depicts an isometric view of a substrate support in accordance with disclosed embodiments.

FIG. 1B depicts a top view of the substrate support of FIG. 1A.

FIG. 1C depicts a cross-sectional side view of the substrate support of FIG. 1A.

FIG. 1D depicts a side view of the substrate support of FIG. 1C with a wafer.

FIG. 1E depicts a cross-sectional side view of the substrate support of FIG. 1A and a single laser source.

FIG. 1F depicts a magnified portion of the substrate support of FIG. 1C.

FIG. 1G depicts the cross-sectional side view of FIG. 1C with additional features.

FIG. 1H depicts a cross-sectional top view slice of the substrate support of FIG. 1G.

FIG. 2A depicts a side view of the substrate support of FIG. 1A along with a wafer.

FIG. 2B depicts a top view of FIG. 1B.

FIG. 3 depicts a cross-sectional side view of another substrate support in accordance with disclosed embodiments.

FIG. 4 depicts an example photoresist film deposition chamber.

FIG. 5 depicts a flow diagram of various operations.

FIG. 6 depicts a graph illustrating deposition rates and temperatures for condensation-based deposition.

### DETAILED DESCRIPTION

In the following description, numerous specific details are set forth in order to provide a thorough understanding of the presented embodiments. The disclosed embodiments may be practiced without some or all of these specific details. In other instances, well-known process operations have not been described in detail to not unnecessarily obscure the disclosed embodiments. While the disclosed embodiments will be described in conjunction with the specific embodiments, it will be understood that it is not intended to limit the disclosed embodiments.

In this application, the terms “semiconductor wafer,” “wafer,” “substrate,” “wafer substrate” and “partially fabricated integrated circuit” are used interchangeably. One of ordinary skill in the art would understand that the term “partially fabricated integrated circuit” can refer to a silicon wafer during any of many stages of integrated circuit fabrication thereon. A wafer or substrate used in the semiconductor device industry typically has a diameter of 200 mm, or 300 mm, or 450 mm. In addition to semiconductor wafers, other work pieces that may take advantage of the disclosed embodiments include various articles such as printed circuit boards, magnetic recording media, magnetic recording sensors, mirrors, optical elements, micro-mechanical devices and the like.

### Introduction and Context

For some semiconductor deposition processes, unwanted backside deposition may occur. These deposition processes include condensation-based deposition processes in which process gases are flowed towards a wafer and caused to condense into particulates that travel onto and become deposited on the wafer surface. During some of these deposition processes, the wafer may be supported by an electrostatic chuck (ESC) that causes a clamping force to be exerted against the wafer to prevent relative movement between the wafer and the ESC. Some ESCs or other wafer supports, such as a pedestal, have a wafer support area that is sized smaller than the wafer which results in a circumferential edge region of the wafer not being in contact with the ESC and exposes a circumferential region of the wafer's backside to the processing chamber environment. As used herein, a substrate support encompasses these various wafer support structures that are configured to support a wafer or substrate, including an ESC (that is configured to exert a clamping force) or a pedestal. During condensation-based deposition operations, the deposition material may flow to and deposit on this exposed backside circumferential region.

Deposition on the backside of a wafer is unwanted for numerous reasons. For example, after condensation-based depositions have been performed on a wafer and caused backside deposition, the wafer may be transferred in a Front-Opening Unified Pod (FOUP). Many FOUPs hold and support a wafer using structures that contact the wafer's edge regions and these structures may contact and abrade the backside deposition, and cause it to flake off and travel onto other wafers in that same FOUP. Further, some of the backside deposition removed by the FOUP support structures' contact and abrasion may remain in the FOUP and contaminate other wafers subsequently loaded into the FOUP.

Many apparatuses and techniques are unable to adequately address this unwanted backside deposition. For instance, apparatuses and techniques do not and/or cannot prevent this deposition. Further, once the unwanted material has been deposited, it can be removed using wet clean operations, but these cleaning operations can reduce throughput, increase costs, and can be difficult to implement. For example, many wet cleaning operations are not integrated into the deposition chamber or tool; rather, they are separate modules or tools that require transferring the wafer to such cleaning modules or tools. The wafer handling involved in this transferring may further contact and abrade the wafer, and thereby dislodge the backside material and cause further contamination. Using cleaning modules or tools also requires additional transferring and processing time, which both decrease throughput, and also requires substantial materials that are costly and require a complex liquid storage and delivery system that can be difficult to operate and maintain.

The present inventors determined novel and unique apparatuses and techniques to reduce and/or prevent unwanted backside deposition from occurring during condensation-based deposition processes. Many condensation-based deposition processes are temperature dependent and therefore have a deposition rate that may approach or reach zero at and above a particular temperature. During condensation-based deposition processes, the wafer is maintained at one or more setpoint temperatures that have a desired deposition rate to cause the material to be deposited on the wafer. The present inventors determined that the deposition of the material could be reduced or prevented by heating and maintaining the exposed circumferential edge region of the wafer at or above the temperature at which the deposition rate is at or near zero. This creates a temperature differential between the circumferential edge region, which may have a radial thickness of between about 0.5 mm and 5 mm, and the remaining inner region of the wafer. In some implementations, the inner region may be most of the wafer, such as for a 300 mm wafer, the radius of this inner region may be between about 145 mm and 149 mm, for example. The circumferential edge region may be the rest of the wafer between the outer boundary of the inner region and the edge of the wafer.

The apparatuses provided herein create this temperature differential between the wafer's inner region and the circumferential edge region by radiatively heating the exposed circumferential edge region using one or more light sources, such as light emitted by a plurality of light emitting diodes, for instance, a vertical-cavity surface-emitting lasers (VCSEL), or a laser emitted through lenses connected via fiberoptic cable to one or more laser sources.

### Substrate Supports

Aspects of this disclosure pertain to apparatuses for radiatively heating a circumferential edge region of a wafer to prevent unwanted backside deposition during condensation-based deposition processes. As mentioned above, material is deposited on an inner region of a wafer while the wafer's temperature is maintained at one or more setpoint temperatures that cause the material to be deposited on the front side of the wafer at a particular deposition rate. During deposition, the wafer may be supported by a wafer support structure, such as an ESC or pedestal, and this structure may have a wafer heating unit with one or more heating zones that is configured to heat and maintain the inner region of the wafer at the setpoint temperature at which the desired deposition rate occurs. As used herein, a substrate support encompasses these various wafer support structures that are configured to support a wafer or substrate, including an ESC (that is configured to exert a clamping force) or a pedestal. Concurrently during this deposition on the inner region of the wafer, the circumferential edge region may be heated to and maintained at a temperature higher than the setpoint temperature, such as the temperature at which the deposition rate is at or near zero, in order to reduce or prevent deposition from occurring in the circumferential edge region.

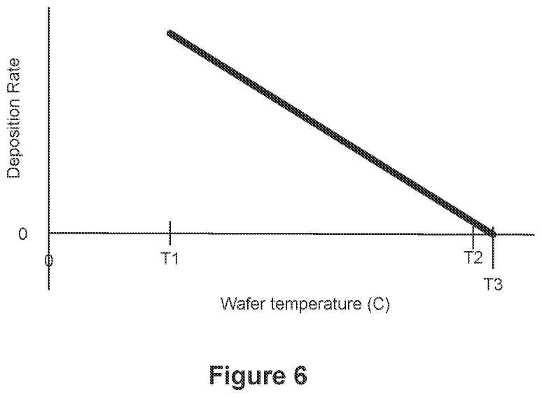

As noted above, many condensation-based deposition processes are temperature-based deposition processes that may have a deposition rate at or near zero at one or more temperature ranges. At temperature ranges below this point, the deposition rate may be positive and cause material deposition. FIG. 6 depicts a graph illustrating deposition rates and temperatures for condensation-based deposition. The vertical axis is deposition rate and the horizontal axis is temperature and as can be seen here, the deposition rate decreases as the temperature of the wafer increases. At temperatures T1 to T2, the deposition rate is positive, but at and above temperature T3, the deposition rate becomes zero. This relationship between temperature and deposition is used to prevent or reduce the unwanted backside deposition on the wafer. For the particular deposition process chemistry, the circumferential edge region is heated near, at, or above the associated T3 temperature where the deposition rate is zero. In some implementations, T1 and T2 may range between about 30° C. to 150° C., and T3 may be greater than or equal about 60° C. and about 200° C.

As mentioned above, the apparatuses herein radiatively heat the exposed circumferential edge region using light emitted by one or more light sources, such as a plurality of light emitting diodes, for instance, a plurality of VCSELs, or a laser emitted through a plurality of lenses connected via fiberoptic cable to one or more laser sources. Radiatively heating this circumferential edge region creates a thermal gradient through the wafer thickness that may be more uniform than conductively heating this area of the wafer; in some instances, using conductive heating creates one or more undesirable localized hot spots on the wafer and takes longer to ramp up and ramp down than the one or more light sources.

The one or more light sources are configured to emit light with wavelengths that can be absorbed by silicon wafers. The use radiative heaters with silicon, whether doped or un-doped, requires careful selection and configuration because the light's wavelengths must be at least partially absorbed by silicon to heat the silicon. However, silicon only absorbs particular wavelengths and is transparent to many wavelengths, such as infrared which is used in common radiative heaters. Here, the light emitted by the one or more light sources is chosen to be absorbed by silicon thereby enabling the light to heat the silicon. In some implementations, these wavelengths of the light emitted by the one or more light sources for heating the circumferential edge region include, for example, between about 400 nanometers (nm) and about 800 nm, between about 200 nm and about 1,300 nm, between about 500 nm and about 1,100 nm, between about 800 nm and about 1,300 nm, and between about 700 nm and about 1,000 nm. For instance, silicon can absorb light having a wavelength of about 800 nm to a depth of about 1 mm in the silicon.

In some embodiments, the apparatuses may further create the temperature differential between the inner region and the circumferential edge region by using an active cooling zone in the substrate support to prevent the thermal energy in the circumferential edge region from being conducted towards the inner region. The elevated temperate, and therefore the elevated thermal energy, in the circumferential edge region naturally radiates inwards, but this heat conduction to the inner region is unwanted because any additional thermal energy in the inner region may disrupt the tight and precise temperature control this region and adversely affect the deposition therein. The active cooling zone may be enabled by an active cooling unit that has a circumferential cooling fin that is thermally connected to coolant channels and that extends around, and radially offset outside of, the one or more heating zones of the wafer heating unit. The circumferential cooling fin acts as a thermal barrier and heat exchanger; the heat from the circumferential edge region is conducted to the circumferential cooling fin and the coolant channels thereby removing the excess heat from the wafer. In some implementations a thermal insulator is radially interposed between the circumferential cooling fin and the one or more heating zones of the wafer heating unit to prevent unwanted heat removal from the inner region by the circumferential cooling fin.

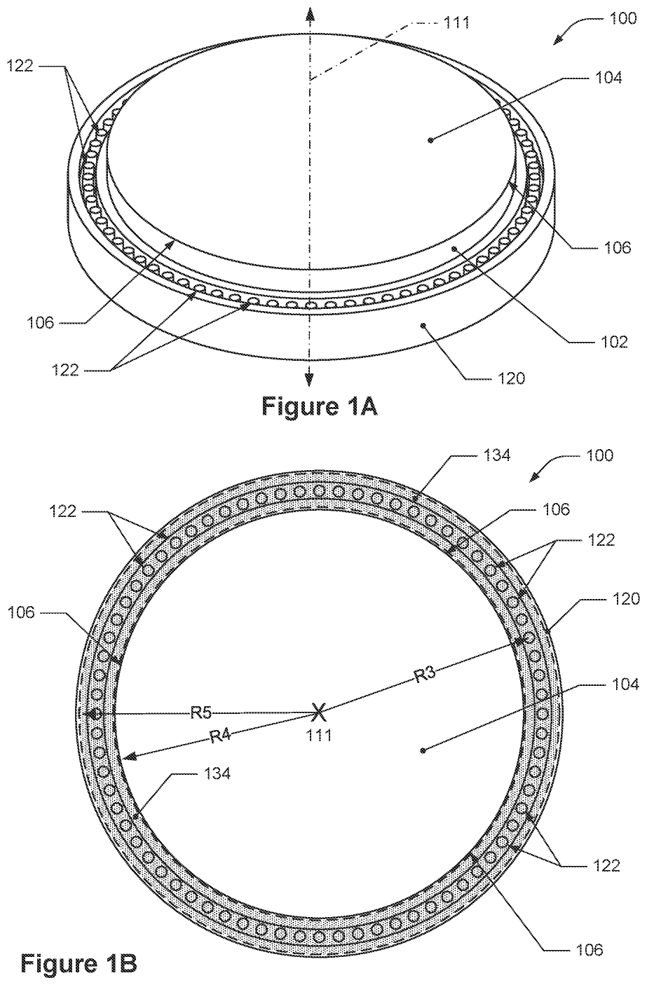

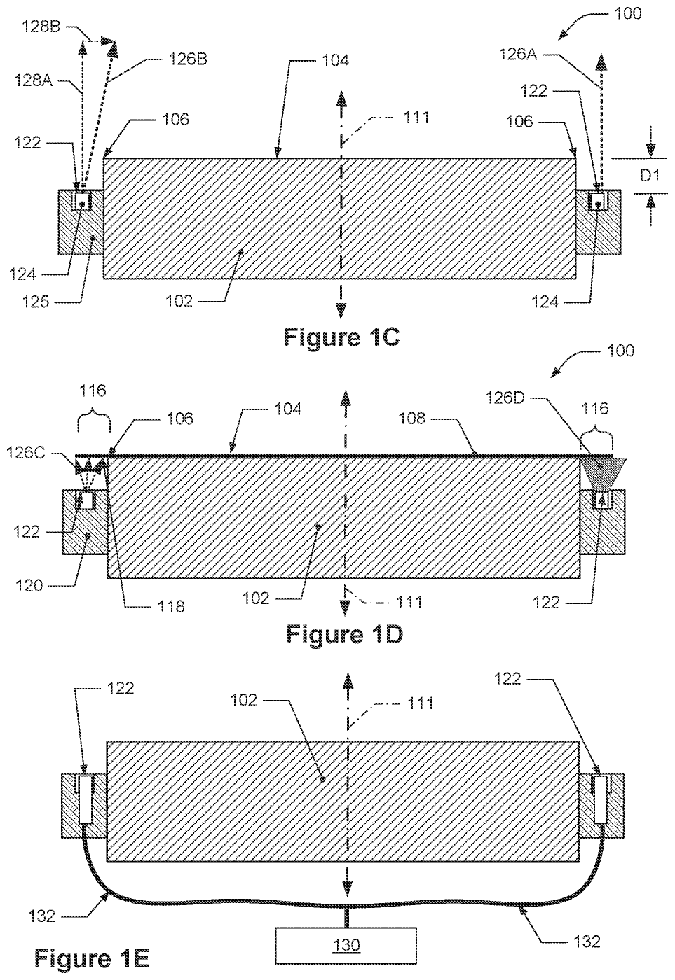

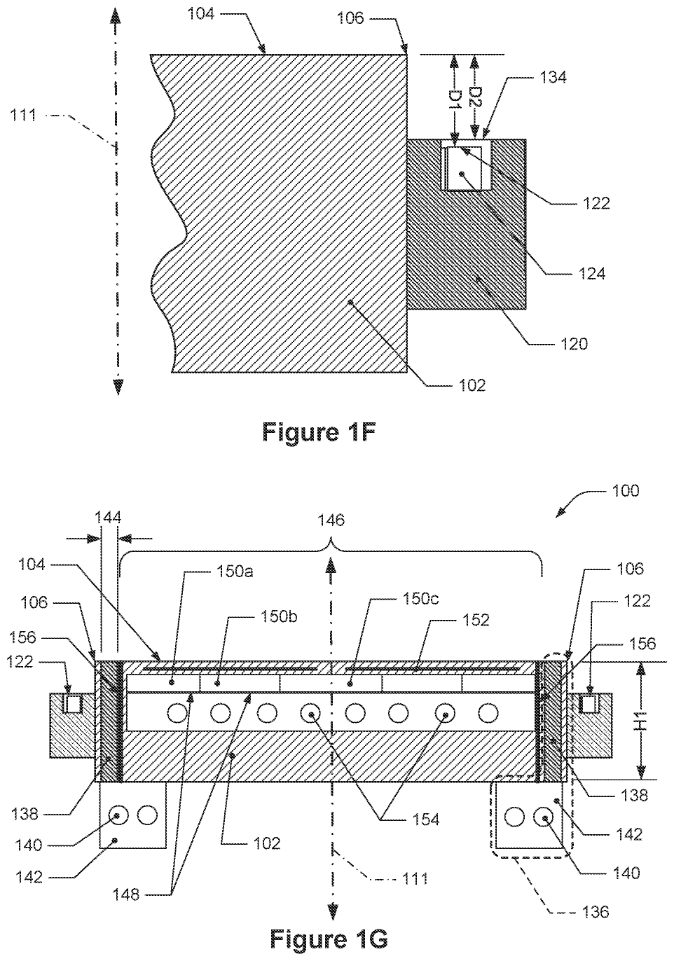

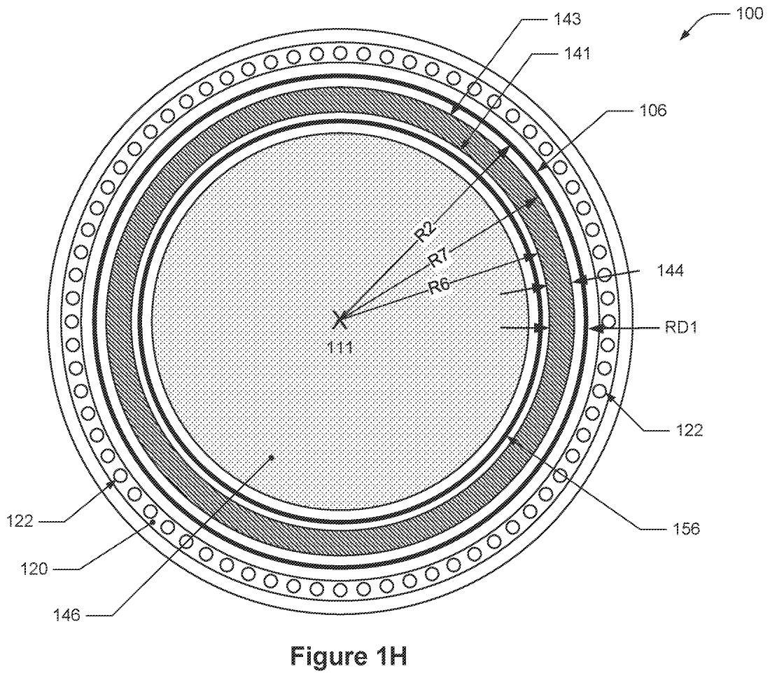

FIG. 1A depicts an isometric view of a substrate support in accordance with disclosed embodiments. The substrate support 100 includes a base plate 102 with a wafer support area 104 on a top of the base plate 102. The wafer support area 104 is configured to support a wafer placed thereon and is at least partially defined by an outer boundary 106 that may be, as shown, circular or substantially circular (e.g., within 5% of circular due to manufacturing tolerances). In some instances, the wafer support area 104 may have a planar surface, as shown in FIG. 1A, while in some other instances the wafer support area 104 has a nonplanar topography, such as grooves or cylindrical contact areas.

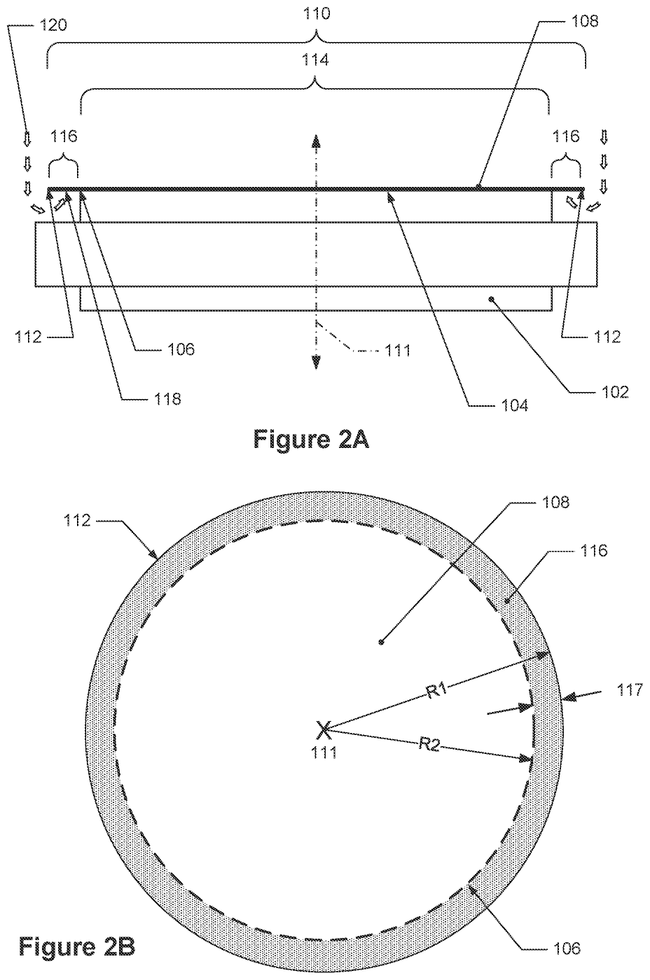

For many substrate supports, the wafer support area 104 has a smaller surface area and diameter than the wafer it supports which result in a circumferential edge region of the wafer not being in contact with or supported by the substrate support. FIG. 2A depicts a side view of the substrate support of FIG. 1A along with a wafer and FIG. 2B depicts a top view of FIG. 1B. In FIG. 2A, a wafer 108 is positioned on the wafer support area 104 and the wafer's surface area 110 and outer diameter 112 are larger than the wafer support area's surface area 114 and outer boundary 106 which results in a circumferential edge region 116 of the wafer 108 extending past the outer boundary 106 of the wafer support area 104 and not being in contact with or supported by the substrate support. The outer diameter 112, or outer edge, of the wafer is therefore radially offset farther from the substrate support's center axis 111 than the outer boundary 106 of the wafer support area 104.

These wafer and substrate support geometries are further illustrated in FIG. 1B which shows the wafer 108 above the wafer support area and its boundary 106 which is depicted with dashed lines to illustrate it is underneath the wafer 108 and not visible from this Figure's angle. The circumferential edge region 116 is also highlighted with shading. As can be seen, the outer diameter 112, or outer edge, of the wafer 108 is radially offset by a radius R1 which is farther from the substrate support's center axis 111 (illustrated as an X in the center of the Figure) than the outer boundary 106 of the wafer support area 104 which is radially offset from the center axis 111 by a radius R2 that is smaller than radius R1. The center axis 111 may be considered to run longitudinally along the substrate support 100 and may be perpendicular to the wafer support area 104. In some implementations, the circumferential edge region 116 may have a radial thickness 117 between about 5 mm and about 0.5 mm, including about 4 mm, about 3.5 mm, about 3 mm, about 2.5 mm, about 2 mm, about 1.5 mm, or about 1 mm, for instance.

As shown in FIGS. 2A and 2B, this circumferential edge region 116 of the wafer 108 overhangs the substrate support and is exposed to the processing chamber environment which can lead to unwanted backside deposition on the wafer in this region. For example, in FIG. 2A, process gases and material can flow around the wafer edge 112 and become deposited on the wafer's backside 118 in the circumferential edge region 116 as illustrated with arrows 120. To prevent this backside deposition, the substrate supports provided herein have an optical wafer edge heating unit configured to radiatively heat the wafer's circumferential edge region to a temperature or temperature range at which point the condensation-based deposition does not occur, or occurs at an acceptably low rate, and thereby reduces and/or prevents this unwanted backside deposition. The optical wafer edge heating unit radiatively heats by emitting light of particular wavelengths from one or more light sources, such as individual light emitting diodes or a laser source. The emitted light passes through one or more light emission surfaces that distribute the light onto and around the wafer's circumferential edge region. In some embodiments, there may be one light emission surface and in other embodiments, there may be a plurality of light emission surfaces.

Referring back to FIG. 1A, the substrate support 100 includes an optical wafer edge heating unit 120 having one or more light sources and a plurality of light emission surfaces. The light emission surfaces 122, some of which are identified, are represented by circular surfaces. It will be understood that these surfaces may be a surface through which light passes, such as a lens connected to a fiberoptic cable, a surface of an LED, a surface of a VCSEL, and/or an exterior surface covering a LED (e.g., a case over the LED). In FIG. 1B, which depicts a top view of the substrate support of FIG. 1A, the plurality of light emission surfaces 122 is more visible. The plurality of light emission surfaces 122 extends around and encircles the outer boundary 106 of the base plate 102 when viewed along the substrate support's center axis 111; these light emission surfaces 122 are also positioned radially outwards from, and therefore have a greater radial distance from the center axis 111, than the outer boundary 106. In some implementations, each of the light emission surfaces 122 may be radially offset from the center axis 111 by the same, or substantially the same (e.g., within 10%), radial distance R3. This radial distance R3 may be measured from a center point, or average nominal point, of each light emission surface 122. In some other implementations, at least one light emission surface 122 may be offset at a different radial distance than one or more other light emission surfaces 122.

The light emitting surfaces 122 are also positioned vertically below the wafer support area 104 when the substrate support is viewed from the side, e.g., viewed along an axis perpendicular to the center axis 111. FIG. 1C depicts a cross-sectional side view of the substrate support of FIG. 1A. The wafer support area 104, its outer boundary 106, and two of the light emission surfaces 122 are seen in FIG. 1C. The light emission surfaces 122 are positioned along the center axis 111 such that they are offset from and below the outer boundary 106 by a first offset distance D1 that is a non-zero distance. This first offset distance D1 may range between about 0.5 mm and about 20 mm, between about 1 mm and about 10 mm, between about 3 mm and about 20 mm, and between about 5 mm and about 10 mm, for example.

The light emission surfaces 122 are positioned and configured to direct light towards the backside 118 of the circumferential edge region 116 of the wafer (not shown here in FIG. 1C; see FIG. 1D) that is positioned on the wafer support area 104. The light may be emitted from the light emission surfaces 122 in various manners, such as different degrees of collimated light as well as diffuse light. The degree of collimation may vary based on different aspects of the optical wafer edge heating unit, including whether a lens is used and the light source, for instance. For example, a laser diode, such as a VCSEL, has light that is less collimated than a laser light from a gas or crystal laser emitted through a lens. Additionally, a LED that emits visible light may emit diffuse light. Due to this, the light emitted from the light emission surfaces 122 may have different directional components including in at least a direction having a directional component parallel to the center axis 111. For example, in FIG. 1C, two example beams of light are illustrated with light beam 126A being a vector that is parallel to the center axis 111 and light beam 126B being a vector that is non-parallel to the center axis 111, but has a first directional component 128A parallel to the center axis 111 and a second directional component 128B perpendicular to the center axis 111.

In some implementations, the light emission surfaces 122 may be angled with respect to the center axis 111 and/or tangentially with respect to the outer boundary 106 in order to create overlapping beams of light emitted onto the wafer. In FIG. 1C, this angling may be about an axis perpendicular to the page of the Figure and about another axis that is perpendicular to the center axis 111.

FIG. 1D, which depicts a side view of the substrate support of FIG. 1C with a wafer, illustrates the wafer edge heating unit directing light onto the wafer. Here, the wafer 108 is positioned on the wafer support area 104 and the circumferential edge region 116 is seen extending past the outer boundary and positioned over the plurality of light emission surfaces 122 as discussed above. The optical wafer edge heating unit 120 is seen causing light to be emitted through, or by, the light emission surfaces 122 and onto the circumferential edge region 116, including onto the backside 118 of the wafer 108, to heat the circumferential edge region 116. The emitted light is illustrated as beams 126C and diffuse 126D to show non-limiting examples of how light may be emitted onto the wafer 108 to heat the circumferential edge region 116.

As provided above, in some implementations the optical wafer edge heating unit 120 may have a plurality of light sources that are light emitting diodes (LEDs), including LEDs that emit visible light and those that emit a laser, such as a VCSEL. In some such embodiments, the light emission surfaces 122 may be considered a part of the LED light sources such that each light emission surface is a part of a corresponding light source. For example, the light emission surface may be a diode that emits the light, or for a VCSEL, the light emission surface may be the exterior surface of the VCSEL since the laser is generated in a stack of materials, e.g., between mirrors and oxide layers. In some embodiments, these LEDs emit light having wavelengths that include, for example, between about 400 nanometers (nm) and about 800 nm, between about 800 nm and about 1,300 nm,, between about 200 nm and about 1,200 nm, between about 500 nm and about 1,100 nm, between about 800 nm and about 1,300 nm, and between about 700 nm and about 1,000 nm. These wavelengths are able to be absorbed by the silicon wafer and thereby heat the wafer to at least about 80° C., about 100° C., about 110° C., about 120° C., about 130° C., about 140° C., about 150° C., about 160° C., about 170° C., about 180° C., about 190° C., and about 200° C., for example.

By using LEDs, the light emission sources and the light emission surfaces may all be positioned within the optical wafer edge heating unit 120 as illustrated in FIG. 1C. Here, a light emission source 124 is represented by a box that includes the light emission surface 122, both of which are contained within the housing 125 of the optical wafer edge heating unit 120. In some implementations, each of these light emission sources 124 may be electrically connected to each other in series in order to simplify and unify their powering. In some other implementations, sub-groups of these light emission sources 124 may be electrically connected together in order to facilitate different powering schemes, and thus different heating schemes to create adjustable heating areas in the optical wafer edge heating unit 120. This adjustability may enable more fine tuning of the temperature profile in the circumferential edge region of the wafer.

The number of the light sources included in the optical wafer edge heating unit may vary. In some implementations, the number of light sources, e.g., LEDs or VCSELs, may be less than about 100, about 150, about 200, about 250, about 300, about 350, about 400, about 450, or about 500, for example.

In some implementations, the light source of the optical wafer edge heating unit may be a single laser source that is separate from the substrate support, such as outside the processing chamber in which the substrate support is placed. The single laser source may be connected to a plurality of fiber optic cables that spans between the laser source and the substrate support. Each fiber optic cable may terminate at a lens which may be the light emission surface. FIG. 1E depicts a cross-sectional side view of the substrate support of FIG. 1A and a single laser source. As can be seen, the single laser source 130 is a separate structure than the substrate support 100 and is connected to a plurality of fiber optic cables 132, each of which terminates at the light emission surface 122, two of which are shown and may be considered a lens.

The number of light emission surfaces, e.g., lenses, connected to the single laser source 130 for the optical wafer edge heating unit of FIG. 1E may vary. In some implementations, the number of light emission surfaces, e.g., lenses, may be less than about 100, about 150, about 200, about 250, about 300, about 350, about 400, about 450, or about 500, for example. This may include one light emission surface.

In some of these embodiments, the light emission surfaces 122 connected to the fiber optic cables may be oriented at a perpendicular angle with respect to the center axis, like depicted in FIG. 1C. In some other embodiments, the light emission surfaces 122 may be oriented a non-perpendicular angle with respect to the center axis 111, such as an acute or an obtuse angle.

Similar to the LEDs, the laser source 130 emits laser light having wavelengths that include, for example, between about 400 nanometers (nm) and about 800 nm, between about 200 nm and about 1,200 nm, between about 800 nm and about 1,300 nm, between about 500 nm and about 1,100 nm, and between about 700 nm and about 1,000 nm. These wavelengths are able to be absorbed by the silicon wafer and thereby heat the wafer to at least about 80° C., about 100° C., about 110° C., about 120° C., about 130° C., about 140° C., about 150° C., about 160° C., about 170° C., about 180° C., about 190° C., or about 200° C., for example.

Because some process gases and/or cleaning gases used in processing chambers may be harmful to the one or more light sources and/or light emission surfaces, some implementations may use a window to cover and protect the one or more light sources and/or light emission surfaces from these gases. The window may be comprised of a material transparent to the light wavelengths emitted by the one or more light sources, including light having wavelengths in the range of between about 400 nm to 1,500 nm, for example. In some embodiments, this material may be quartz, sapphire, quartz with a sapphire coating, or calcium fluoride (CaF).

In some embodiments, the substrate support may have a single window that is positioned over the plurality of light emission surfaces. Referring to FIG. 1B, the substrate support 100 includes a window 134 that has an annular, ring-shape represented as shading with a dashed inner boundary 131 and outer boundary 133. As can be seen, the window 134 extends around the center axis 111 and covers the light emission surfaces 122. The inner radius R4 of the inner boundary 131 of the window 134 may be smaller than the radius R3 of the light emission surfaces 122, and the radius R5 of the outer boundary 133 of the window 134 may be larger than the radius R3. Other features of the window and substrate support are further illustrated in FIG. 1F which depicts a magnified portion of the substrate support of FIG. 1C. As can be seen here, the window is above the light emission surfaces 122 such that the window is positioned along the center axis 111 between the outer boundary 106 and the light emission surfaces 122. Additionally, the window 134 is offset from the outer boundary 106 by a distance D2, parallel to center axis 111, that is less than the offset distance D1 of the light emission surfaces 122 from the outer boundary 106.

In some embodiments, the substrate support may have a plurality of windows positioned over one or more light emission surfaces. This may include, for example, multiple annular sector shaped portions that each extend partially around the center axis. This may also include, for example, square, circular, obround, elliptical, or other geometric shaped windows. In some instances, the substrate support may have a number of windows that corresponds with the number of light emission surfaces such that each window corresponds with one light emission surface, i.e., each light emission surface has its own corresponding window. In some embodiments that have a lens connected to a fiberoptic cable and laser sources, the lens itself may be the window and may therefore be comprised of the material that is transparent to the light wavelengths emitted by the one or more light sources, such as quartz, sapphire, quartz with a sapphire coating, or calcium fluoride (CaF). In some implementations, the thickness of the window may be between about 0.5 mm and about 15 mm, or about 1 mm and 10 mm, for example.

The one or more windows of the substrate support may also be connected to the substrate support, including to the optical wafer edge heating unit in order to create one or more plenum volumes around the light emission surfaces in order to fluidically isolate the light emission surfaces from the processing chamber environment. This may include positioning the light emission surfaces in a housing 125 or other structure that, together with the one or more windows, creates the sealed plenum volume(s). In some embodiments, a fluid may be flowed within this plenum volume, such as a cooling fluid, which may be an inert gas like argon, nitrogen, or helium. This fluid may be used to control the temperature of the optical wafer edge heating unit. The substrate support may have one or more inlets and one or more outlets for flowing this gas within the plenum volume. The one or more inlets are fluidically connected to the inert gas source outside the chamber, which may include through fluid conduits that may be at least partially routed inside the substrate support. The one or more outlets are fluidically connected to an exhaust or other environment outside the chamber, which may also be through fluid conduits running within the pedestal.

The substrate support provided herein may also include other temperature control elements. For example, as provided above, it is desirable to create a temperature differential between the circumferential edge region and the inner region of the wafer where deposition is intended to occur, but because the optical wafer edge heating heats the circumferential edge region to a higher temperature than the inner region, the added thermal energy in the edge region may naturally be conducted radially inwards to the inner region. This inwards thermal conduction is unwanted because it may affect the precise temperature control of the inner region for the deposition processes and thereby adversely affect the deposition, such as increasing wafer non-uniformity. The substrate support may therefore include an active cooling unit to create a thermal break, or heat sink, that removes the added thermal energy in the circumferential edge region. The active cooling unit may include coolant channels and a circumferential cooling fin in the base plate of the substrate support that extends around the center axis, is radially inwards from the plurality of light emission surfaces, and is thermally connected to the cooler.

FIG. 1G depicts the cross-sectional side view of FIG. 1C with additional features. Here, the substrate support 100 has the active cooling unit 136, encompassed within the dashed shape, which includes a circumferential cooling fin 138 thermally connected (e.g., physically connected to or connected via thermally conductive materials such as a metal or metal alloy) to one or more cooling channels 140 in a housing 142. The circumferential cooling fin 138 is positioned radially inwards from the plurality of light emission surfaces 122 such that the circumferential cooling fin 138 is closer to the center axis 111 than the light emission surfaces 122; in some instances, the circumferential cooling fin 138 may be radially inwards of the optical wafer edge heating unit 120 as also illustrated in FIG. 1G. The cooling channels 140 are configured to receive a heat transfer fluid, such as water, that is cooled to a low temperature, such as about −20° C. This may include having the cooling channels 140 fluidically connected to a chiller or cooler that is outside the processing chamber where the substrate support is located. The housing 142 having the cooling channels 140 is thermally connected to the circumferential cooling fin 138 such that a thermal pathway exists between the circumferential cooling fin 138 and the cooling channels 140 in order for the heat received by the circumferential cooling fin 138 to be removed from the substrate support 100.

The circumferential cooling fin 138 may have a relatively small radial thickness and may be positioned close to the outer boundary of the substrate support to be close to the heated circumferential edge region. Having the circumferential cooling fin 138 configured and positioned in such a manner allows for the wafer's area where deposition occurs to be closer to the outer boundary 106, and thus larger, which advantageously provides more area for deposition and device creation, thereby increasing yield of the wafer. Accordingly, in some implementations, the radial thickness 144 of the circumferential cooling fin 138 may be less than or equal to about 4 mm, about 3 mm, about 2 mm, or about 1 mm. In some embodiments, the circumferential cooling fin 138 may be positioned within a radial distance from the outer boundary 106 that may be less than or equal to about 4 mm, about 3 mm, about 2 mm, about 1 mm, about 0.5 mm, or about 0.25 mm, for example.

The configuration of the substrate support and circumferential cooling fin is further illustrated in FIG. 1H which depicts a cross-sectional top view slice of the substrate support of FIG. 1G. The optical wafer edge heating unit 120 and light emission surfaces 122 are seen radially offset outside of, and extending around, the outer boundary 106 of the substrate support 100; for clarity, the outer boundary 106 is depicted in a heavy bold line. The circumferential cooling fin 138, depicted with cross-hatching, is also seen extending around and encircling the center axis 111 of the substrate support 100 and positioned radially inwards towards the center axis 111 from the outer boundary 106. The circumferential cooling fin 138 has an inner boundary 141 with an inner radius R6 and an outer boundary 143 with an outer radius R7 that together at least partially define the radial thickness 144 of the circumferential cooling fin 138.

As illustrated in FIG. 1H, in some implementations the circumferential cooling fin 138 may be radially offset from the outer boundary 106 such that the radius R2 of the outer boundary 106 is larger than the outer radius R7 of the circumferential cooling fin 138. In some other implementations, the circumferential cooling fin 138 may overlap with the outer boundary 106 which may include, for instance, the circumferential cooling fin 138 being a part of the external structure of the substrate support. The area of the substrate support 100 radially inwards of the circumferential cooling fin 138 may be the area of the wafer on which deposition occurs. This inwards area, represented by a shaded circular area 146, of the substrate support may heat a wafer positioned thereon to a different temperature than the circumferential edge region using a wafer heating unit with one or more heating zones.

As provided above, it is desirable to reduce the radial thickness of the circumferential cooling fin 138 in order to enlarge the area on which deposition occurs. Therefore, in some implementations, the radial thickness 144 of the circumferential cooling fin 138 may be less than or equal to about 4 mm, about 3 mm, about 2 mm, or about 1 mm, for example. Further, it may be advantageous to position the circumferential cooling fin 138 close to the outer boundary 106, including overlapping with the outer boundary 106. In some such embodiments, as shown in FIG. 1H, the inner radius R6 of the circumferential cooling fin 138 may be radially offset from the outer boundary 106 by a radial distance RD1, perpendicular to the center axis 111, less than about 4 mm, about 3 mm, about 2 mm, or about 1 mm, for example. This distance enables the active cooling zone to be close to the circumferential annular region which is desirable because it enlarges the remaining region of the wafer radially inwards from the circumferential cooling fin 138 that may be heated to the deposition temperature and used for deposition, thereby increasing the wafer's yield.

Referring back to FIG. 1G, additional features of the substrate support 100 are shown, including the wafer heating unit 148 that may be considered a thermal control system for controlling the temperature of the wafer during processing. In FIG. 1G, the wafer heating unit 148 is a multi-zone thermal control system featuring three annular resistance heater traces 150a, 150b, and 150c that are concentric with one another and positioned beneath clamping electrodes 152. The center resistance heater traces 150a, 150b, and 150c may, in some implementations, fill a generally circular area, and each resistance heater trace 150a, 150b, and 150c may follow a generally serpentine or otherwise meandering path within a corresponding annular region. Each resistance heater trace 150a, 150b, and 150c may be individually controlled to provide a variety of radial heating profiles in the substrate support; such a three-zone heating system may, for example, be controlled to maintain the wafer so as to have a temperature uniformity of ±0.5° C. in some cases. While the substrate support 100 features a three-zone heating system, other implementations may use single-zone or multi-zone heating systems having more or fewer than three zones.

As shown in FIGS. 1G, in some implementations the wafer heating unit 148 is separate from the optical wafer edge heating unit 120. The wafer heating unit 148 is seen positioned inside the substrate support base plate, while the light emission surfaces 122 are radially offset from and encircle the one or more heating zones of the wafer heating unit 148. The circumferential cooling fin 138 is also radially interposed, with respect to the center axis 111, between the wafer heating unit 148 and the light emission surfaces 122.

In some implementations, for example, temperature control mechanisms of the wafer heating unit 148 may use heat pumps instead of resistance heating traces. For example, in some implementations, the resistance heater traces may be replaced by, or augmented by, Peltier junctions or other, similar devices that may be controlled to “pump” heat from one side thereof to another. Such mechanisms may be used, for example, to draw heat from the wafer support area 104 (and thus the wafer) and direct it into the base plate 102 and heat exchange passages 154, thereby allowing the wafer to be heated or cooled more rapidly and more effectively, if desired.

The substrate support 100 may also include, a heat dispersion or cooling system 153 that may include one or more heat exchange passages 154 that are arranged in a generally distributed fashion throughout the base plate 102, e.g., the heat exchange passages 154 may follow a serpentine, circular switchback, or spiral pattern around the center of the base plate 102. A heat exchange medium, e.g., water or inert fluorinated liquid, may be circulated through the heat exchange passages 154 during use. The flow rate and temperature of the heat exchange medium may be externally controlled so as to result in a particular heating or cooling behavior in the base plate 102.

In some implementations, it may not be feasible for the cooling system 153 to act as the cooling system for both the inner region 146 of the substrate support base plate 102, e.g., for the inner portion of the wafer where deposition occurs, and for the active cooling unit 136. As mentioned above, in order to create the wafer temperature differential between the circumferential edge region and the wafer's inner region, some implementations remove the additional heat in the circumferential edge region by actively cooling a circumferential region of the wafer using temperatures configured to remove the excess heat in this edge region. In contrast, the cooling system 153 is configured to cool and provide temperature control of temperatures of the wafer heating unit 148 which are lower than the temperatures of the circumferential edge region. Because of this, during processing operations, the cooling system 153 is configured to cool the temperatures of the wafer heating unit 148, and therefore remove a desired amount of heat and thermal energy from the wafer heating unit 148 which is less than the heat and thermal energy in the circumferential edge region. The cooling system 153 may therefore be unable to remove enough heat from the circumferential edge region that is at a higher temperature than the inner portion of the wafer.

For example, the wafer heating unit 148 may heat a wafer to 50° C. and the cooling system 153 is configured to cool the wafer heating unit 148 in order to maintain this temperature. While the inner portion of the wafer is at 50° C., the optical wafer edge heating unit may heat the circumferential edge region of the wafer to 75° C. The active cooling unit 136 is configured to cool the wafer from 75° C. to 50° C., while the cooling system 153 is configured to cool the wafer heating unit 148 in order to maintain the lower 50° C. Because of this, the cooling system 153 may be unable to remove enough heat to adequately cool the circumferential edge region from 75° C. to 50° C.

In some implementations, it may be advantageous to include a thermal insulator between the circumferential cooling fin and the wafer heating system in order to thermally isolate the active cooling unit from the wafer heating system. As mentioned above, the wafer heating system is used to precisely, accurately, and uniformly heat the wafer during deposition and the circumferential cooling fin may remove heat from the wafer heating system and adversely affect the desired temperature profile on the wafer and resulting deposition. Referring back to FIG. 1G, the substrate support 100 includes a thermal insulator 156 radially interposed, with respect to the center axis 111, between the circumferential cooling fin 138 and the wafer heating unit 148. FIG. 1H also depicts this thermal insulator 156. In some embodiments, the thermal insulator may be an air gap while in some instances it may be a ceramic, such as an aluminum oxide, a polymer, such as a polyether ether ketone (PEEK), an elastomer, such as a silicone rubber, an aerogel, or a quartz.

In FIG. 1G, the substrate support 100 also includes an electrostatic clamping electrode system, which may have one or more clamping electrodes 152 that may be used to generate an electric charge within the wafer positioned on the wafer support area 104 that causes the substrate to be drawn against the wafer support area 104. In some instances, there are two clamping electrodes that provide a bi-polar electrostatic clamping system and in other implementations, only a single clamping electrode may be used to provide a mono-polar electrostatic clamping system.

The configuration of the active cooling unit and the optical wafer edge heating unit may vary in different implementations. As shown in FIGS. 1F, the optical wafer edge heating unit 120, including the plurality of light emission surfaces 122, is positioned above the housing 142 with the cooling channels 140 of the active cooling unit 136. In such embodiments, the plurality of light emission surfaces 122 are positioned along the center axis 111 interposed between the wafer support area 104 and the cooling channels 140.

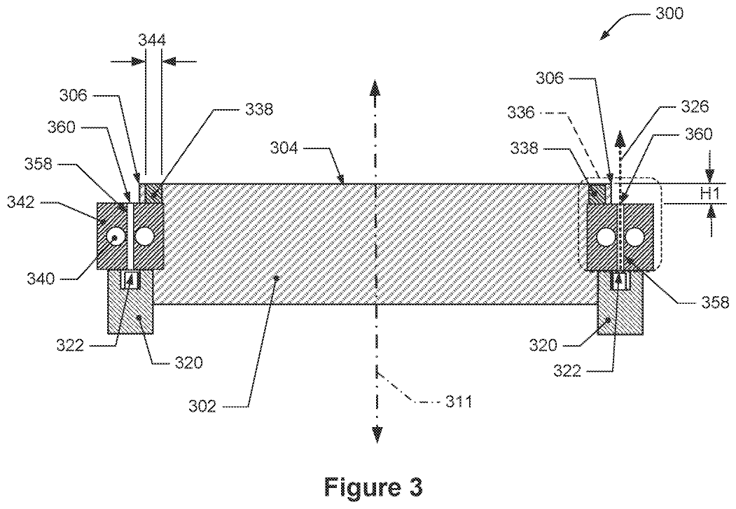

In some other embodiments, the plurality of light emission surfaces may be positioned below the housing with the cooling channels and configured to emit light onto the wafer through one or more ports in the housing. FIG. 3 depicts a cross-sectional side view of another substrate support in accordance with disclosed embodiments. Here, the substrate support 300 may be configured similarly or the same as provided above except for noted differences. The substrate support 300 in FIG. 3 includes an active cooling unit 336 with a circumferential cooling fin 338 that extends around the center axis 311 and has a smaller height H2 along the center axis 311 than the height H1 of the circumferential cooling fin 138 of FIG. 1G. The shorter circumferential cooling fin 338 is enabled by positioning the housing 342 with the cooling channels 340 closer to the wafer support area 304 than the optical wafer edge heating unit 320. In some implementations, this positioning and configuration of the active cooling unit 336 may advantageously cool less of the substrate support 300 base plate 302, thereby decreasing its thermal effect on the rest of the substrate support, and also may use or require less cooling to achieve the desired temperature on the wafer support area 304 because the thermal pathway between the housing 342 and the wafer support area 304.

Further in FIG. 3, the optical wafer edge heating unit 320, including the plurality of light emission surfaces 322, is positioned below the active cooling unit 336. This results in the coolant channels 340 and housing 342 being positioned along the center axis 311 between the outer boundary 306 and the optical wafer edge heating unit 320 and plurality of light emission surfaces 322. To enable this positioning, the active cooling unit 336 is configured to enable light emitted by the plurality of light emission surfaces 322 to pass through the housing 342 and onto the wafer. As shown in FIG. 3, the housing 342 includes one or more ports 358, such as a hole, slot, or other opening, through which light from the plurality of light emission surfaces 322 may pass to the wafer positioned on the wafer support area 304. The one or more ports 358 are connected to the light emission surfaces 322 such that light passing through the light emission surfaces 322, such as light 326, passes through the one or more ports 358 in order to reach the wafer on the wafer support area 304.

In some implementations, similar to above, the one or more ports 358 may have a window 334 positioned thereon and/or therein to protect the one or more ports 158 and/or the light emission surfaces 322 from the process gases. The window 334 may be configured as discussed above, including being transparent to light from the light emission surfaces 322, having lensing to direct the light in various manners, and being made of a material such as quartz or sapphire. In FIG. 3, a window 360 is shown at an end of the ports 358.

The features of the substrate supports described herein are applicable to any structure used to support a substrate, such as an electrostatic chuck (ESC) with one or more clamping electrodes or a pedestal that does not have clamping electrodes.

### Apparatuses and Deposition Techniques

The substrate supports provided herein may be used as part of various deposition processing chambers and techniques. Some such processing is Extreme ultraviolet (EUV) lithography. EUV lithography makes use of EUV resists that are patterned to form masks for use in etching underlying layers. EUV resists may be polymer-based chemically amplified resists (CARs) produced by liquid-based spin-on techniques.

Spin-on techniques, which are a form of a “wet” film formation technique, involve placing a flat substrate on a turntable, depositing an amount of liquid film constituent at the center of the substrate, and then rotating the substrate at a generally high speed, e.g., 20 to 80 rotations per second for 30 to 60 seconds, to produce a highly uniform thickness film. Dip-coating is another type of wet film formation technique in which the substrate is oriented with its major faces parallel to the vertical direction and then immersed in a bath of the liquid film constituent and then withdrawn. Due to the use of a liquid constituent, however, “wet” film formation techniques may not be well-suited for coating non-flat substrates, e.g., substrates with preexisting feature patterns etched in the exposed upper surface thereof. For example, if the substrate is not flat, e.g., has existing features patterned into the surface-to-be-coated, the liquid constituent will tend to fill those features, leading to a variable film thickness between non-featured portions of the substrate and featured portions of the substrate (while the uppermost surface of the deposited film may be nominally planar and uniform, the depths of the deposited film may vary with underlying feature presence).

Dry deposition techniques, also referred to as vapor deposition techniques, as well as other similar techniques, in contrast, deliver the film constituent to the substrate as a vapor-phase reactant, where it then condenses or adsorbs onto the exposed surface of the substrate in a generally conformal, even-thickness layer. As a result, the thickness of the deposited film layer may generally remain uniform across the substrate, regardless of whether in a featured or unfeatured region of the substrate. It is to be understood that such deposition techniques are not viewed as “wet” techniques even if, in some cases, there is condensation of the film constituent on the target substrate. Another key advantage to dry deposition processes such as are discussed herein is that such processes may be performed in a range of different temperature and pressure environments, and are often performed at sub-atmospheric conditions. This allows for much smaller amounts of the reactants to be used to produce a given photoresist film than would be necessary to produce an equivalent film using a wet deposition process. This reduces the material cost for providing such films over providing equivalent films using wet deposition techniques. Dry deposition processes also incur a lower throughput penalty, as the substrates that are produced are able to be prepared for subsequent processing phases at a greater rate since there is little or no need to dry the substrate after applying the photoresist layer.

The metal oxide-containing film can be patterned directly (i.e., without the use of a separate photoresist) by EUV exposure in a vacuum ambient providing sub-30 nm patterning resolution. Generally, the patterning involves exposure of the EUV resist with EUV radiation to form a photo pattern in the resist, followed by development to remove a portion of the resist according to the photo pattern to form the mask. The mask may then be used in subsequent processing operations, e.g., etch processes

Directly photopatternable EUV resists may be composed of or contain metals and/or metal oxides mixed within organic components. The metals/metal oxide-containing materials are highly promising in that they can enhance the EUV photon adsorption and generate secondary electrons and/or show increased etch selectivity to an underlying film stack and device layers.

The EUV-sensitive metal or metal oxide-containing film may be dry-deposited on the substrate. Some characteristics of suitable compositions, materials and dry deposition processing operations in accordance with this disclosure are described in which is hereby incorporated herein by reference for the disclosure of these methods and materials applicable to the present disclosure. Such methods include those where polymerized organometallic materials are produced in the vapor phase and deposited on a substrate. In particular, methods for making EUV-patternable thin films on a surface of a semiconductor substrate may include: mixing a vapor stream of an organometallic precursor with a vapor stream of a counter-reactant so as to form a polymerized organometallic material; and depositing the organometallic polymer-like material onto the surface of the semiconductor substrate. In some embodiments, more than one organometallic precursor is included in the vapor stream. In some embodiments, more than one counter-reactant is included in the vapor stream. In some embodiments, the mixing and depositing operations are performed in a continuous chemical vapor deposition (CVD), an atomic layer deposition (ALD) process, or ALD with a CVD component, such as a discontinuous, ALD-like process in which metal precursors and counter-reactants are separated in either time or time and space, e.g., in some ALD-type processes, one or more organometallic precursors may be flowed onto a substrate and the substrate may then be moved to another processing station or to another processing chamber where one or more counter-reactants may be flowed onto the substrate. It will be understood that reference herein to simply “reactants” is intended to refer to both the organometallic precursor and the counter-reactant, e.g., “simultaneous flow of the reactants” would refer to simultaneous flow of the organometallic precursor and the counter-reactant.

Following deposition, the EUV-patternable thin film is patterned by exposing the wafer with the thin film to a beam of EUV light that is passed through an optical mask having features to be patterned on the wafer, typically under relatively high vacuum, and then removing the wafer from vacuum and optionally performing a post exposure bake in ambient air. The exposure results in one or more exposed regions, such that the film includes one or more unexposed regions that have not been exposed to EUV light. Further processing of the coated substrate may exploit chemical and physical differences in the exposed and unexposed regions.

Substrates may include any material construct suitable for photolithographic processing, particularly for the production of integrated circuits and other semiconductor-based devices. In some embodiments, such substrates may be silicon wafers. Substrates upon which features have been created (“underlying features”) may have an irregular surface topography (as referred to herein, the “surface” is a surface onto which a film of the present disclosure is to be deposited or that is to be exposed to EUV during processing). Such underlying features may include regions in which material has been removed (e.g., by etching) or regions in which materials have been added (e.g., by deposition) during processing prior to conducting a method of this disclosure. Such prior processing may include methods of this disclosure or other processing methods in an iterative process by which two or more layers of features are formed on the substrate.

As discussed earlier, EUV-sensitive thin films may be deposited on a substrate to create a mask layer. Such EUV-sensitive films may be operable as resists for subsequent EUV lithography and processing and may include materials which, upon exposure to EUV, undergo changes, such as the loss of bulky pendant substituents bonded to metal atoms in low density M-OH rich materials, that allow their crosslinking to denser M-O-M bonded metal oxide materials, where M is a metal with a high EUV absorption cross-section. Through EUV patterning, areas of the film are created that have altered physical or chemical properties relative to unexposed areas. These properties may be exploited in subsequent processing, such as to dissolve either unexposed or exposed areas, or to selectively deposit materials on either the exposed or unexposed areas. In some embodiments, the unexposed film has a more hydrophobic surface than the exposed film under the conditions at which such subsequent processing is performed. For example, the removal of material may be performed by leveraging differences in chemical composition, density and cross-linking of the film. Removal may be by wet processing or dry processing, as further described below.

The thin films are, in various embodiments, organometallic materials, for example organotin materials comprising SnOx, or other metal oxides materials/moieties. The organometallic compounds may be made in a vapor phase reaction of an organometallic precursor with a counter-reactant. In various embodiments, the organometallic compounds are formed through mixing specific combinations of organometallic precursors having bulky alkyl groups or fluoroalkyl with counter-reactants and polymerizing the mixture in the vapor phase to produce a low-density, EUV-sensitive material that deposits onto the substrate.

In various embodiments, organometallic precursors may include at least one alkyl group on each metal atom that can survive the vapor-phase reaction, while other ligands or ions coordinated to the metal atom can be replaced by the counter-reactants. Organometallic precursors include those of the formula MₐR_{b}L_{c} where M is a metal with a high EUV absorption cross-section; R is alkyl, such as CₙH₂ₙ₊₁, preferably wherein n≥3; L is a ligand, ion or other moiety which is reactive with the counter-reactant; a≥1; b≥1; and c≥1.

In various embodiments, M has an atomic absorption cross section equal to or greater than 1·10⁷ cm²/mol. M may be, for example, be a material such as tin, bismuth, antimony, tellurium, or combinations of two or more thereof. In some embodiments, M is tin. R may be fluorinated, e.g., having the formula CₙFₓH₂ₙ₊₁. In various embodiments, R has at least one beta-hydrogen or beta-fluorine. For example, R may be an i-propyl, n-propyl, t-butyl, i-butyl, n-butyl, sec-butyl, n-pentyl, i-pentyl, t-pentyl, sec-pentyl, or a mixture of two or more thereof. L may be any moiety readily displaced by a counter-reactant to generate an M-OH moiety, such as a moiety that is an amine (such as a dialkylamino or monalkylamino group), an alkoxy group, a carboxylate, a halogen, or mixtures of two or more thereof.

Organometallic precursors may be any of a wide variety of candidate metal-organic precursors. For example, where M is tin, such precursors include t-butyl tris(dimethylamino) tin, i-butyl tris(dimethylamino) tin, n-butyl tris(dimethylamino) tin, sec-butyl tris(dimethylamino) tin, i-propyl(tris)dimethylamino tin, n-propyl tris(diethylamino) tin, and analogous alkyl(tris)(t-butoxy) tin compounds such as t-butyl tris(t-butoxy) tin. In some embodiments, the organometallic precursors may be partially fluorinated.

Counter-reactants may be selected to have the ability to replace the reactive moieties, ligands or ions (e.g., L in Formula 1, above) so as to link at least two metal atoms via chemical bonding. Counter-reactants can include water, peroxides (e.g., hydrogen peroxide), di- or polyhydroxy alcohols, fluorinated di- or polyhydroxy alcohols, fluorinated glycols, and other sources of hydroxyl moieties. In various embodiments, a counter-reactant reacts with the organometallic precursor by forming oxygen bridges between neighboring metal atoms. Other potential counter-reactants include hydrogen sulfide and hydrogen disulfide, which can crosslink metal atoms via sulfur bridges.

The thin films may include optional materials in addition to an organometallic precursor and counter-reactants to modify the chemical or physical properties of the film, such as to modify the sensitivity of the film to EUV or to enhance etch resistance. Such optional materials may be introduced, for example, by doping during vapor phase formation prior to deposition of the film on the substrate, after deposition of the film, or both. In some embodiments, a gentle remote H₂ plasma may be introduced so as to replace some Sn-L bonds with Sn—H, which can increase reactivity of the resist under EUV.

In various embodiments, the EUV-patternable films may be deposited on the substrate using vapor deposition equipment and processes among those known in the art. In such processes, the polymerized organometallic material may be formed in vapor phase or in situ on the surface of the substrate. Suitable processes for forming such polymerized organometallic material on a substrate include, for example, depositing it using chemical vapor deposition (CVD), atomic layer deposition (ALD), or ALD with a CVD component, such as a discontinuous, ALD-like process in which metal precursors and counter-reactants are separated in either time or time and space.

In general, methods may include mixing a vapor stream of an organometallic precursor with a vapor stream of a counter-reactant so as to form a polymerized organometallic material, and then depositing the organometallic material onto the surface of the semiconductor substrate. As will be understood by one of ordinary skill in the art, the mixing and depositing aspects of the process may be concurrent, in a substantially continuous process.

In an exemplary continuous CVD process, two or more gas streams, in separate inlet paths, of organometallic precursor and source of counter-reactant may be introduced into a deposition chamber of a CVD apparatus, where they may mix and react in the gas phase to form agglomerated polymeric materials (e.g., via metal-oxygen-metal bond formation). The streams may be separately introduced into the deposition chamber, for example, using separate injection inlets or via a dual-plenum showerhead. The apparatus may be configured so that the flows of organometallic precursor and counter-reactant are mixed in the deposition chamber, allowing the organometallic precursor and counter-reactant to react to form the polymerized organometallic material. Without limiting the mechanism, function or utility of present technology, it is believed that the product from such vapor-phase reaction becomes heavier in molecular weight as metal atoms are crosslinked by counter-reactants, and is then condensed or otherwise deposited onto the substrate. In various embodiments, the steric hindrance of the bulky alkyl groups prevents the formation of densely packed networks and produces porous, low density films.

The CVD process is generally conducted at reduced pressures, such as from 10 milliTorr to 10 Torr. In some embodiments, the process is conducted at from 0.5 to 2 Torr. The temperature of the substrate may preferably be kept at or below the temperature of the reactant streams. For example, the substrate temperature may be from 0° C. to 250° C., or from ambient temperature (e.g., 23° C.) to 150° C. In various processes, deposition of the polymerized organometallic material on the substrate may occur at rates inversely proportional to surface temperature.

The thickness of the EUV-patternable film formed on the surface of the substrate may vary according to the surface characteristics, materials used, deposition duration, and processing conditions. In various embodiments, the film thickness may range from 0.5 nm to 100 nm and the overall absorption of the resist film may be 30% or less (e.g., 10% or less, or 5% or less) so that the resist material at the bottom of the resist film is sufficiently exposed. In some embodiments, the film thickness is from 10 to 20 nm. Without limiting the mechanism, function or utility of present disclosure, it is believed that, unlike wet, spin-coating processes of the art, the processes of the present disclosure have fewer restrictions on the surface adhesion properties of the substrate, and can therefore be applied to a wider variety of substrates. Moreover, as discussed above, the deposited films may closely conform to surface features, providing advantages in forming masks over substrates, such as substrates having underlying features, without “filling in” or otherwise planarizing such features.

The deposited film may be patterned by exposing one or more regions of the film to EUV light, e.g., using a scanner or other lithography photopattern transfer tool. EUV devices and imaging methods among those useful herein include methods known in the art. In particular, as discussed above, exposed areas of the film that are created through EUV patterning may have altered physical or chemical properties relative to unexposed areas of the film. For example, in exposed areas, metal-carbon bond cleavage may occur via beta-hydride elimination, leaving behind reactive and accessible metal hydride functionality that can be converted to hydroxide and cross-linked metal oxide moieties via metal-oxygen bridges, which can be used to create chemical contrast either as a negative tone resist or as a template for hard mask. In general, a greater number of beta-H in the alkyl group results in a more sensitive film. Following exposure, the film may be baked, e.g., at a temperature of 150 to 250° C., so as to cause additional cross-linking of the metal oxide film. The difference in properties between exposed and unexposed areas may be exploited in subsequent processing, such as to dissolve unexposed areas or to deposit materials on the exposed areas. For example, the pattern can be developed using a dry method to form a metal oxide-containing mask.

Such dry development processes can be done by using either a gentle plasma (high pressure, low power) or a thermal process, either of which may be performed while flowing a hydrogen halide dry development chemistry such as HBr or HCl. In some embodiments, the hydrogen halide is able to quickly remove the unexposed material, leaving behind a pattern of the exposed film that can then be transferred into the underlying substrate layers by subsequent application of plasma-based etch processes, for example conventional etch processes.

Suitable plasma-based dry development processes may include the use of transformer coupled plasma (TCP), inductively coupled plasma (ICP), or capacitively coupled plasma (CCP) processes, and may be implemented using equipment and techniques among those known in the art. For example, a plasma-based development process may be conducted at a pressure of >5 mT (e.g., >15 mT), at a power level of <1000 W (e.g., <500 W). Temperatures may be from 0 to 300° C. (e.g., 30 to 120° C.), at flow rate of 100 to 1000 standard cubic centimeters per minute (sccm), e.g., about 500 seem, for from 1 to 3000 seconds (e.g., 10-600 seconds).

In thermal development processes, the substrate may be exposed to dry development chemistry. Suitable chambers for performing such thermal development processes may include a vacuum line, one or more dry development chemistry gas lines to provide dry developments chemistry gases to the chamber, and heaters to allow for temperature control of the chamber. In some embodiments, the chamber interior may be coated with corrosion-resistant films, such as organic polymers or inorganic coatings. One such coating is polytetrafluoroethene ((PTFE), e.g., Teflon™). Such materials can be used in thermal processes of this disclosure, although such a coating may not be appropriate for plasma-based processes due to the risk of removal by plasma exposure.

Current EUV resist coating technology typically uses a spin-on photoresist which is applied in atmospheric environment, e.g., at typical atmospheric pressures. This technique does not generally allow for atmospheric control or influence and only allows only a single chemical mixture to be applied for the entire film stack. Spin-on techniques also do not provide for uniform photoresist layer thickness for substrates having non-planar surfaces on which the film is to be formed.

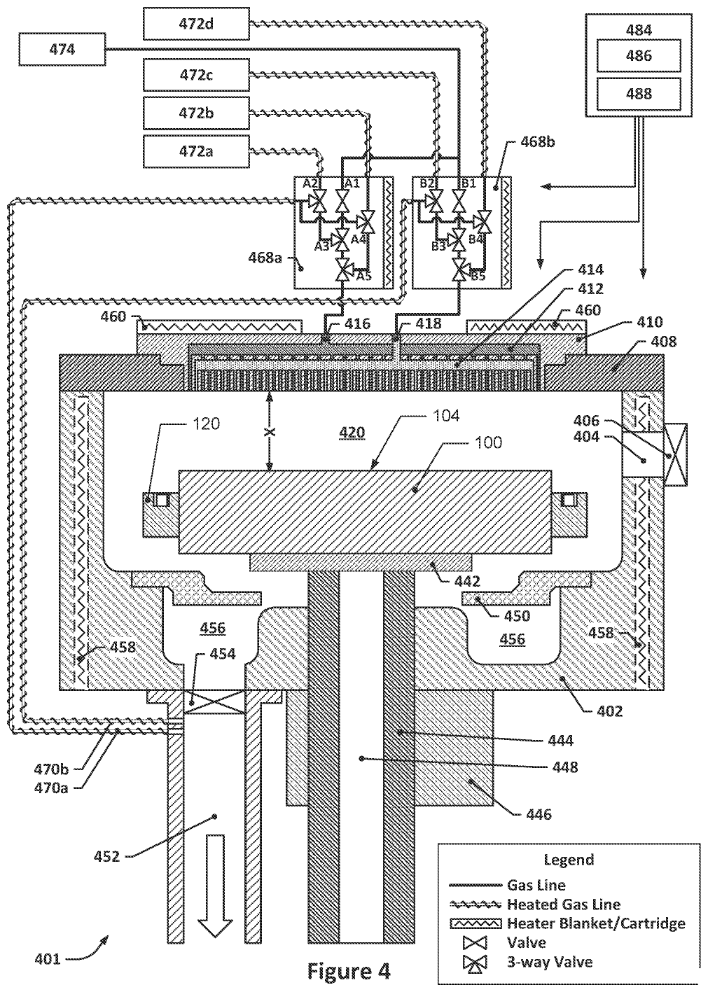

As mentioned earlier, dry deposition techniques may be used to create photoresist layers that do not suffer from the thickness non-uniformity issues that wet-deposited techniques suffer from with regard to substrates with pre-existing features. Such dry deposition techniques may be performed using a photoresist film deposition chamber. An example photoresist film deposition chamber is depicted in FIG. 4.

In FIG. 4, an apparatus 401 is depicted that has a processing chamber 402 that includes a lid 408. The processing chamber 402 may include a wafer transfer passage 404 through one of the walls of the processing chamber 402 that is sized to allow a substrate 422 to be passed therethrough and into the interior of the processing chamber 402, where the substrate 422 may be placed on an substrate support 400 which may be any of the substrate supports described herein above, including substrate support 100 or 300. The wafer transfer passage 404 may have a gate valve 406 or similar door mechanism that may be operated to seal or unseal the wafer transfer passage, thereby allowing the environment within the processing chamber 402 to be isolated from the environment on the other side of the gate valve 406. For example, the processing chamber 402 may be provided substrates 422 via a wafer handling robot that is located in an adjoining transfer chamber. Such a transfer chamber may, for example, have multiple processing chambers 402 arranged around its periphery, with each such processing chamber 402 connected with the transfer chamber via a corresponding gate valve 406.

As provided above, the wafer support 424 may be any of the substrate supports provided herein, including the substrate supports in FIGS. 1A-1G and 3, for instance. FIG. 4 depicts the substrate support 400 of FIG. 1C and includes, for example, the optical wafer edge heating unit 120 and wafer support area 104. Although not depicted in FIG. 4, the substrate support 400 may also include the active cooling unit 136 and/or the wafer heating unit 148 described herein above.

The substrate support 400 may, for example, be supported by a wafer support housing 442 that is connected with, and supported by, a wafer support column 444. The wafer support column 444 may, for example, have a routing passage 448 other pass-throughs for routing cabling, fluid flow conduits, and other equipment to the underside of the base plate substrate support 400. For example, while not shown in FIG. 4, cabling for providing electrical power to the optical wafer edge heating unit 120, the active cooling unit 136, and the wafer heating unit 148 may be routed through the routing passage 448, as may cabling for providing electrical power to the clamping electrodes. To avoid undue clutter, such cables and conduits are not depicted in FIG. 4, but it is to be understood that they would, nonetheless, be present.

The apparatus 401 of FIG. 4 also includes a substrate support z-actuator 446 that may provide movable support to the wafer support column 444. The wafer support z-actuator 446 may be actuated to cause the wafer support column 444, and the substrate support 400 supported thereby, to move up or down vertically, e.g., by up to several inches, within a reaction space 420 of the processing chamber 402. In doing so, a gap distance X between the substrate 422 and the underside of the showerhead 410 may be tuned depending on various process conditions.

The apparatus 401 may also include a system for removing process gases from the processing chamber 402 during and after processing concludes. For example, the processing chamber 402 may include an annular plenum 456 that encircles the wafer support column 444. The annular plenum 456 may, in turn, be fluidically connected with a vacuum foreline 452 that may be connected with a vacuum pump, e.g., such as may be located beneath a subfloor below the apparatus 401. A regulator valve 454 may be provided in between the vacuum foreline 452 and the processing chamber 402 and actuated to control the flow into the vacuum foreline 452. In some implementations, a baffle 450, e.g., an annular plate or other structure that may serve to make the flow into the annular plenum 456 more evenly distributed about the circumference of the wafer support column 444, may be provided to reduce the chances of flow non-uniformities developing in reactants flowed across the substrate 422.

The showerhead 410, as shown, is a dual-plenum showerhead 410 and includes a first plenum 412 that is provided process gas via a first inlet 416 and a second plenum 414 that is provided process gas via a second inlet 418. The showerhead 410 may, in some implementations, have more than two plenums, although two plenums is generally the minimum required to maintain separation between the organometallic precursor and the counter-reactant prior to release of the organometallic precursor and the counter-reactant into the reaction space 420 of the processing chamber 402. Each plenum may have a corresponding set of gas distribution ports that fluidically connect the respective plenum with the reaction space 420 through the faceplate of the showerhead 410 (the faceplate being the portion of the showerhead 410 that is interposed between the lowermost plenum and the reaction space 420).

The first inlet 416 and the second inlet 418 of the showerhead 410 may be provided processing gases via a gas supply system, which may be configured to provide one or more organometallic precursors and one or more counter-reactants, as discussed earlier herein.

The depicted apparatus 401, however, is configured to provide multiple organometallic precursors and multiple counter-reactants. For example, a first valve manifold 468a may be configured to provide organometallic precursors to the first inlet 416, while a second valve manifold 468b may be configured to provide counter-reactants to the second inlet 418.

In this example, the first valve manifold 468a, for example, includes multiple valves A1-A5. Valve A2 may, for example, be a three-way valve that has one port fluidically connected with a first vaporizer 472a, another port fluidically connected with a bypass line 470a, and a third port fluidically connected with a port on another 3-way valve A3. Similarly, valve A4 may be another three-way valve that has one port fluidically connected with a second vaporizer 472b, another port fluidically connected with the bypass line 470a, and a third port fluidically connected with a port on another 3-way valve A5. One of the other ports on valve A5 may be fluidically connected with the first inlet 416 while the remaining port on valve A5 may be fluidically connected with one of the remaining ports on the valve A3. The remaining port on the valve A3 may, in turn, be fluidically connected with the valve A1 which may be fluidically interposed between the valve A3 and a purge gas source 474, e.g., nitrogen, argon, or other suitably inert gas (with respect to the organometallic precursor and/or the counter-reactant).

For the purposes of this disclosure, the term “fluidically connected” is used with respect to volumes, plenums, holes, etc., that may be connected with one another in order to form a fluidic connection, similar to how the term “electrically connected” is used with respect to components that are connected together to form an electric connection. The term “fluidically interposed,” if used, may be used to refer to a component, volume, plenum, or hole that is fluidically connected with at least two other components, volumes, plenums, or holes such that fluid flowing from one of those other components, volumes, plenums, or holes to the other or another of those components, volumes, plenums, or holes would first flow through the “fluidically interposed” component before reaching that other or another of those components, volumes, plenums, or holes. For example, if a pump is fluidically interposed between a reservoir and an outlet, fluid that flowed from the reservoir to the outlet would first flow through the pump before reaching the outlet.

The first valve manifold 468a may, for example, be controllable to cause vapors from one or both of the vaporizers 472a and 472b to be flowed either to the processing chamber 402 or through the first bypass line 470a and into the vacuum foreline 452. The first valve manifold 468a may also be controllable to cause a purge gas to be flowed from the purge gas source 474 and into the first inlet 416.

For example, to flow vapor from the first vaporizer 472a into the reaction space 420, the valve A2 may be actuated to cause the vapor from the first vaporizer 472a to first flow into the first bypass line 470a. This flow may be maintained for a period of time sufficient to allow the flow of the vapor to reach steady state flow conditions. After sufficient time has passed (or after a flow meter, if used, indicates that the flow rate is stable), valves A2, A3, and A5 may be actuated to cause the vapor flow from the first vaporizer 472a to be directed to the first inlet. Similar operations with valves A4 and A5 may be performed to deliver vapor from the second vaporizer 472b to the first inlet 416. In some instances, it may be desirable to purge one of the vapors from the first plenum 412 by actuating the valves A1, A3, and A5 so as to cause the purge gas from the purge gas source 474 to be flowed into the first inlet 416. In some additional implementations, it may be desirable to simultaneously flow vapor from one of the vaporizers 472a or 472b in tandem with flowing gas from the purge gas into the first inlet 416. Such implementations may be used to dilute the concentration of the reactant(s) contained in such vapor(s).

It will be appreciated that the second valve manifold 468b may be controlled in a similar manner, e.g., by controlling valves B1-B5, to provide vapors from vaporizers 472c and 472d to the second inlet 418 or to the second bypass line 470b. It will be further appreciated that different manifold arrangements may be utilized as well, including a single unitary manifold that includes valves for controlling flow of both organometallic precursor(s) and counter-reactant(s) to the first inlet 416 and the second inlet 418.

As mentioned earlier, some apparatuses 401 may feature a lesser number of vapor sources, e.g., only two vaporizers 472, in which case the valve manifold(s) 468 may be modified to have a lesser number of valves, e.g., only valves A1-A3.

As discussed above, apparatuses such as apparatus 401, which may be used to provide for dry deposition of photoresist films using organometallic precursors and counter-reactants, may be configured to maintain particular temperature profiles within the processing chamber 402. In particular, such apparatuses 401 may be configured to maintain a substrate at a lower temperature, e.g., at least 25° C. to 50° lower, than most of the equipment of the apparatus 401 that comes into direct contact with the organometallic precursor(s) and the counter-reactant(s). Additionally, the temperature of the equipment of the apparatus 401 that comes into direct contact with the organometallic precursor(s) and the counter-reactant(s) may be kept to an elevated level that is sufficiently high that condensation of the vaporized reactants on the surfaces of such equipment is discouraged. At the same time, the substrate temperature may be controlled to a level that promotes condensation, or at least deposition, of the reactants on the substrate. As described above, the apparatus 401 is also configured to heat the circumferential edge region of the substrate to a temperature higher than the inner region of the substrate in order to prevent or reduce deposition in this edge region.

To provide for such temperature control, various heating systems may be included in the apparatus 401. For example, the processing chamber 402 may have receptacles for receiving cartridge heaters 458, e.g., for a processing chamber 402 that has a generally cylindrical interior volume but a square or rectangular external shape, vertical holes for receiving cartridge heaters 458 may be bored into the four corners of the chamber 402 housing. In some implementations, the showerhead 410 may be covered with heater blankets 460, which may be used to apply heat across the exposed upper surface of the showerhead 410 to keep the showerhead temperature elevated. It may also be beneficial to heat various gas lines that are used to conduct the vaporized reactants from the vaporizers 472 to the showerhead 410. For example, resistive heater tape may be wound around such gas lines and used to heat them to an elevated temperature. As shown in FIG. 4, all of the gas lines that potentially have either an organometallic precursor or a counter-reactant flowing through them are shown as being heated, including the bypass lines 470. The only exceptions are the gas lines from the valve manifolds 468 to the first inlet 416 and the second inlet 418, which may be quite short and may be indirectly heated by the showerhead 410. Of course, even these gas lines may be actively heated, if desired. In some implementations, heaters may be provided proximate to the gate valve 406 to provide heat to the gate valve as well.

The various operational systems of the apparatus 401 may be controlled by a controller 484, which may include one or more processors 486 and one or more memory devices 488 that are operatively connected with each other and that are communicatively connected with various systems and subsystems of the apparatus 401 so as to provide for control functionality for those systems. For example, the controller 484 may be configured to control the valves A1-A5 and B1-B5, the various heaters 458, 460, the vaporizers 472, the regulator valve 454, the gate valve 406, the wafer support z-actuator, and so forth.

The controller 484 may also be configured to control the optical wafer edge heating unit, the active cooler, and the wafer heating unit in order to cause the wafer on the substrate support 400 to have a temperature differential between the wafer's circumferential wafer edge region and inner region, as described above. This may include, for instance, causing the optical wafer edge heating unit to emit light to heat the wafer's circumferential wafer edge region to a second temperature and the wafer heating unit to heat the inner region to a first temperature that is lower than the second temperature. As provided above, the first temperature may be between about 40° C. to 100° C., while the temperature of the circumferential edge region is greater that this temperature, such as greater than or equal to between about 60° C. and 150° C. The controller is further configured to control the active cooling unit to cool the circumferential cooling fin to a third temperature lower than the first temperature, such as to about 20° C. or between about 20° C. and about 100° C.

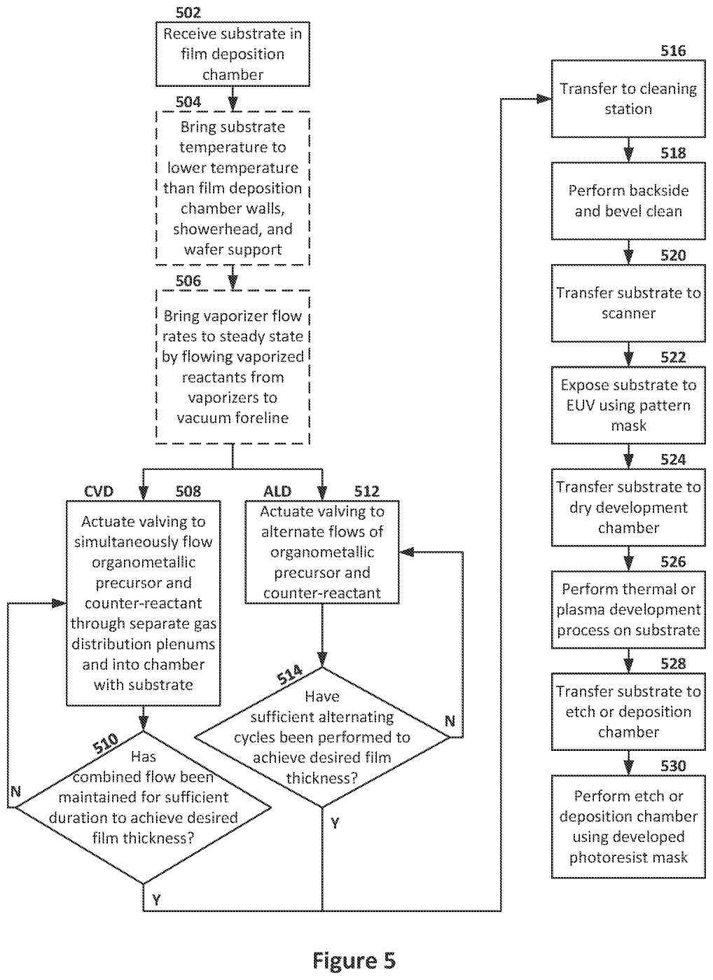

The controller 484 may be configured, e.g., via execution of computer-executable instructions, to cause the apparatus 401 to perform various operations consistent with the disclosure provided above. FIG. 5 depicts a flow diagram of various operations that may be performed in the context of the apparatus 401, as well as subsequent operations that may be performed on a substrate processed in the apparatus 401.

In block 502, for example, the controller 484 may control the apparatus 401 to cause the substrate 422 to be provided to, and placed in, the processing chamber 402. For example, a wafer handling robot may be controlled (or requested) to cause the substrate 422 to be passed through the wafer transfer passage 404 while the gate valve 406 is controlled to be actuated into an open state. The substrate support 400 may, for example, be controlled to be positioned, via the wafer support z-actuator 446, at an appropriate elevation to receive the substrate 422, which may be positioned above (and centered over) the substrate support 400 by the wafer handling robot. Lift pins (not shown) that are part of the substrate support 400 may be caused to be vertically extended from the substrate support 400 to lift the substrate off of an end effector of the wafer handling robot, allowing the wafer handling robot to be retracted from the processing chamber 402 and for the gate valve 406 to be closed, thereby sealing the processing chamber 402. At the same time, the lift pins may be retracted into the substrate support 400 to lower the substrate 422 onto the substrate support 400.

Once the substrate 422 has been loaded in block 502, the wafer heating unit may be controlled to cause the substrate 422 to reach a desired temperature(s) in block 504, including heating the inner region to the second temperature and circumferential edge region to the first temperature higher than the second temperature, as described herein, to prevent or reduce deposition in the edge region. Such control may also include, for example, activating the clamping electrode(s) to provide electrostatic clamping of the substrate 422 to the substrate support 400 and to provide inert gas flow to the gas ports 482 of the substrate support 400 to flow such gas into a backside gap 478 between the substrate 422 and the substrate support 400. For example, the controller 484 may control the various heater systems of the apparatus 401 to maintain the temperature of the interior wall surfaces of the processing chamber 402, the lid 408, and the showerhead 410 to between 80° C. and 120° C., e.g., 100° C. At the same time, the controller 484 may control the wafer heating unit to cause the inner region of the substrate 422 to reach and maintain a temperature of between about 40° C. to 100° C., and control the optical wafer edge heating unit to heat the circumferential edge region of the wafer to a higher temperature, such as greater than or equal to between about 60° C. and 150° C.

In block 506, gas flow from the vaporizers 472 supplying the gas to be used in the dry deposition process may be initiated and allowed to reach steady state, e.g., by causing the valves A1-A5 and B1-B5 to be selectively actuated so as to divert the gas flows from those vaporizers 472 to the bypass lines 470 and into the vacuum foreline 452. Once the flow rates from the selected vaporizers have reached steady state, the technique may then proceed to either block 508 or block 512.

Blocks 508 and 512 represent two alternative approaches to dry-depositing an EUV-sensitive photoresist on the substrate 422. It will be understood that either approach may be used, as appropriate, in the alternative. In the approach of block 508, the controller may be configured to cause an organometallic precursor and a corresponding counter-reactant to be simultaneously dispensed from their respective vaporizers 472 and through respective plenums of the showerhead 410 into the reaction space 420 for a given duration of time. In block 510, a determination may be made if the desired duration of organometallic precursor and corresponding counter-reactant has elapsed (or if the desired amounts of such reactants have been dispensed). If not, then the technique may return to block 508 for further reactant dispensation. If so, then the technique may proceed to block 516, in which the substrate 422 may be removed from the processing chamber 402 and transferred to, for example, a cleaning station or other apparatus. It will be understood that the dry deposition process, at least with respect to the EUV-sensitive photoresist layer deposited in blocks 508 and 510, is essentially complete prior to removal of the substrate 422 from the processing chamber 402. Subsequent portions of the technique of FIG. 5 may occur in other equipment and/or be directed by other controllers if necessary. The technique of blocks 508 and 510 may be referred to as a continuous CVD technique, as the reactants are all flowed simultaneously into the reaction space 420 for a given duration or for a given amount, much as in a CVD process.

In the alternative approach of block 512, the valving of the apparatus 401 may be actuated to alternate flows of the organometallic precursor and the corresponding counter-reactant, e.g., first flow the organometallic precursor through the showerhead 410 and then stop the flow of the organometallic precursor and start the flow of the counter-reactant through the showerhead 410. In some implementations, a purge gas may be flowed through the showerhead 410 in between each reactant flow. These alternating flows may be repeated, if desired, one or more times. For example, in block 514, a determination may be made as to whether the desired number of alternating flow cycles has been performed; if not, then the technique may return to block 512 for performance of a further such flow cycle. If so, then the technique may proceed to block 516. This alternative approach is somewhat similar to atomic layer deposition techniques, in which two different precursors are alternatingly flowed into a deposition chamber. As with the previous simultaneous flow technique, at the conclusion of the alternating flow technique, i.e., after block 514 and prior to block 516, the dry deposition process, at least with respect to the EUV-sensitive photoresist layer deposited in blocks 512 and 514, is essentially complete prior to removal of the substrate 422 from the processing chamber 402.

It will be understood that various permutations and variations of such techniques may be practiced. For example, in some implementations, different organometallic precursors and/or counter-reactants may be used during different stages of an EUV-sensitive photoresist layer deposition process. In one such example, a first organometallic precursor with greater EUV sensitivity may initially be flowed across the substrate to create a first sub-layer of the EUV-sensitive photoresist layer. A second organometallic precursor (different from the first) may then be flowed across the substrate to create a second sub-layer on top of the first sub-layer. This process may be repeated for any number of different organometallic precursors (and/or counter-reactants). Such arrangements may allow the EUV sensitive photoresist layer to be a hybrid of different types of materials. If desired, organometallic precursors may be selected so as to produce sub-layers that have different EUV sensitivities—for example, the first sub-layer may be made using an organometallic precursor that creates a sub-layer that has a greater EUV sensitivity than that of the second sub-layer. This may help, for example, offset potential gradient effects when the deposited EUV-sensitive photoresist film is subjected to EUV exposure. For example, when the deposited EUV-sensitive photoresist film is exposed to EUV light, such light may cause physical or chemical changes in the exposed areas of the photoresist film that can then be leveraged in a post-exposure process, e.g., a developer process. However, such physical or chemical changes may be dependent on the intensity of the EUV radiation. Since the EUV radiation tends to decrease in intensity as a function of increasing penetration depth into the photoresist film due to absorption of some of the energy by upper sub-layers of the photoresist film, the exposure intensity for the lower sub-layer(s) in the photoresist film may be less than in the upper sub-layer(s). As a result, in photoresist films that are made of the same material throughout their entire thickness, the amount of physical or chemical change that is generated through the EUV exposure process may vary as a function of film depth. In some such instances, the duration of such exposure may also affect this variation.

However, by tailoring the photoresist film to utilize different materials for different sub-layers, it may be possible to reduce the variation in physical or chemical change that occurs throughout the thickness of the photosensitive film. For example, if a lower sub-layer is made of a material that is more sensitive to EUV exposure than an upper sub-layer, then this may help compensate for the reduced EUV exposure intensity experienced by that lower sub-layer.

It will be appreciated that such tailoring techniques may have significant benefits in the context of EUV processing, both in terms of throughput and quality. For example, in order to expose the lowest sublayer(s) of a single-material photoresist film to an amount of EUV sufficient to cause the desired level of chemical or physical change in that/those sub-layer(s), it may be necessary to continue to expose the photosensitive film for a much longer period of time than is required to achieve the same level of chemical of physical change in the upper sub-layer(s). This additional exposure time could, for example, be used to perform EUV exposure on another substrate, i.e., results in decreased throughput. Given the extreme cost of EUV processing equipment (an EUV scanner, for example, can cost on the order of $100 million+ (US)), minimizing processing time for EUV scanning operations is highly desirable in order to maximize the return on the investment made into the EUV scanner).

Longer exposure times may also result in decreased quality in the photopattern that is transferred to the photosensitive film through the EUV exposure process. For the nanometer-scale feature sizes that require resort to EUV processing, even the smallest movements of the EUV mask (the mask through which the EUV light is directed in order to produce the desired photopattern on the substrate) relative to the substrate can be significant in terms of feature size. For example, for a feature of 30 nm width, a 5 nm shift in the EUV mask relative to the substrate during the exposure process can result in a ˜15% decrease in full depth feature width. While EUV scanners are designed to minimize the potential for such occurrences, the longer the exposure process takes for a given substrate, the larger the risk is of such movements being encountered (or, more likely, the larger the risk is of encountering more lower-magnitude movements that, in aggregate, have an increased negative effect than the movements do individually).

It will be readily apparent that tailoring the material makeup of such photoresist films using the techniques discussed herein may, for example, allow for reduced exposure times that increase throughput and increase the likelihood of obtaining higher-quality photopatterns. The conformal nature of dry-deposited photoresist films also contributes towards achieving such throughput improvements, as the relatively uniform film thickness avoids scenarios where variations in total film thickness result that require increased EUV exposure time.

As noted earlier, wet deposition of such EUV-sensitive photoresist films are generally not suitable for tailored film deposition since it is not possible to use different materials for different sub-layers of wet-deposited EUV-sensitive photoresist films. Moreover, wet deposition techniques are not conformal in nature. The dry-deposition techniques and equipment discussed herein thus provide significant improvements over wet-deposition techniques and equipment using similar chemistries.

Another example of a dry-deposition technique that may be practiced with the above-described apparatus is one in which different organometallic sub-layers are deposited on the substrate 422 using different dry deposition processes. For example, the technique of blocks 512 and 514 may be used to deposit a thin sub-layer of a first EUV-sensitive photoresist material on the substrate 422 that may, for example, enhance the adsorption or condensation of reactants used to produce a subsequently applied sub-layer of a second, different EUV-sensitive photoresist material. In this sense, the first photoresist material may be used as a “seed sub-layer” to enhance adhesion of the second photoresist material. In such implementations, it may be preferable to use the technique of blocks 512 and 514, which may be more easily controlled to produce thinner sub-layers, for the seed sub-layer, and to then switch to the technique of blocks 508 and 510, which may provide a higher, but not as finely controllable, deposition rate that may be used to provide a thicker sub-layer of the second EUV-sensitive photoresist.

Once the EUV-sensitive photoresist film has been deposited on the substrate 422, the substrate 422 may, as noted above, be transferred to one or more subsequent processing chambers or tool for additional operations. The remaining blocks of FIG. 5 summarize such additional operations for one such implementation, although other implementations may involve other operations or other orders of operations.

For example, subsequent to the completion of the dry deposition processes of blocks 508/510 and/or 512/514, the substrate 422 may be transferred to a cleaning station in block 516 which may be controlled to perform, for example, backside and/or bevel cleaning operations on the substrate 422 in block 518. Following such post-deposition cleaning, the substrate may then be transferred into an EUV scanner system or similar photolithography tool in block 520. In block 522, the EUV scanner may be controlled to apply a photopattern to the substrate using a pattern mask that causes various portions of the substrate 422 to be either exposed to EUV radiation or occluded from such exposure. The exposure process may be continued for as long as is necessary in order to achieve the desired degree of EUV exposure in the exposed regions of the photoresist film on the substrate 422.

After sufficient EUV exposure has been provided to the substrate 422 by the EUV scanner, the substrate 422 may be transferred to a dry development chamber in block 524 and then subjected to a dry development process, such as a thermal- or plasma-based development process. During such a development process, one or the other of the EUV-exposed portions of the substrate 422 and the non-exposed portions of the substrate 422 may be removed using a development process, e.g., dry development process as discussed earlier above, to produce the desired feature mask on the substrate 422.

After the feature mask has been created on the substrate 422, the substrate 422 may be removed from the dry development chamber and provided in block 528 to a process chamber, e.g., a deposition or etch chamber. A suitable semiconductor processing operation, e.g., an etch process or deposition process, may then be performed in block 530 using the feature mask that was provided using the patterns EUV-sensitive photoresist film.

In some implementations, the controller may be part of a larger system. Such systems may include semiconductor processing equipment, including a processing tool or tools, chamber or chambers, a platform or platforms for processing, and/or specific processing components (a wafer pedestal, a gas flow system, etc.). These systems may be integrated with electronics for controlling their operation before, during, and after processing of a semiconductor wafer or substrate. The electronics may be referred to as the “controller,” which may control various components or subparts of the system or systems. The controller, depending on the processing requirements and/or the type of system, may be programmed to control any of the processes disclosed herein, including the delivery of processing gases, temperature settings (e.g., heating and/or cooling), pressure settings, vacuum settings, power settings, radio frequency (RF) generator settings, RF matching circuit settings, frequency settings, flow rate settings, fluid delivery settings, positional and operation settings, wafer transfers into and out of a tool and other transfer tools and/or load locks connected to or interfaced with a specific system.

Broadly speaking, the controller may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the controller in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication of one or more layers, materials, metals, oxides, silicon, silicon dioxide, surfaces, circuits, and/or dies of a wafer.

The controller, in some implementations, may be a part of or coupled to a computer that is integrated with, coupled to the system, otherwise networked to the system, or a combination thereof. For example, the controller may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g. a server) can provide process recipes to a system over a network, which may include a local network or the Internet. The remote computer may include a user interface that enables entry or programming of parameters and/or settings, which are then communicated to the system from the remote computer. In some examples, the controller receives instructions in the form of data, which specify parameters for each of the processing steps to be performed during one or more operations. It should be understood that the parameters may be specific to the type of process to be performed and the type of tool that the controller is configured to interface with or control. Thus as described above, the controller may be distributed, such as by comprising one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example systems may include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an atomic layer deposition (ALD) chamber or module, an atomic layer etch (ALE) chamber or module, an ion implantation chamber or module, a track chamber or module, and any other semiconductor processing systems that may be associated or used in the fabrication and/or manufacturing of semiconductor wafers.

As noted above, depending on the process step or steps to be performed by the tool, the controller might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

It will be generally understood that reference to “films,” “photoresist films,” “deposited layers,” “sub-layers,” and the like in the context of the dry deposition techniques discussed herein is intended to be inclusive of EUV-sensitive photoresist films, even if not explicitly indicated as such.

It will also be understood that the various components of the apparatus may be made a variety of suitable materials. For example, as discussed earlier, the top plate of the substrate support may be made from a ceramic material, which may serve to electrically insulate the clamping electrodes embedded within (as well as the resistive heater elements embedded within) as well as to protect the base plate located underneath. The upper edge ring and the lower edge rings may similarly be made of a ceramic material, if desired. Other structures, such as the processing chamber itself, the showerhead, the base plate of the substrate support, and the wafer support housing, may be made of a material such as an aluminum alloy, and may, in some instances, be anodized or otherwise coated with a protective coating. Materials such as aluminum are relatively inexpensive to machine, provide good chemical resistance when properly coated, and offer excellent heat conduction performance, allowing them to be easily heated to a desired operating temperature.

It should also be understood that the while present disclosure relates to lithographic patterning techniques and materials exemplified by EUV lithography, it is also applicable to other next-generation lithographic techniques. In addition to EUV, which includes the standard 13.5 nm EUV wavelength currently in use and development, the radiation sources most relevant to such lithography are DUV (deep-UV), which generally refers to use of 248 nm or 193 nm excimer laser sources, X-ray, which formally includes EUV at the lower energy range of the X-ray range, as well as e-beam, which can cover a wide energy range. The specific methods may depend on the particular materials and applications used in the semiconductor substrate and ultimate semiconducting device. Thus, the methods described in this application are merely exemplary of the methods and materials that may be used in present technology.

It is to be understood that the phrases “for each <item> of the one or more <items>,” “each <item> of the one or more <items>,” or the like, if used herein, are inclusive of both a single-item group and multiple-item groups, i.e., the phrase “for . . . each” is used in the sense that it is used in programming languages to refer to each item of whatever population of items is referenced. For example, if the population of items referenced is a single item, then “each” would refer to only that single item (despite the fact that dictionary definitions of “each” frequently define the term to refer to “every one of two or more things”) and would not imply that there must be at least two of those items. Similarly, the term “set” or “subset” should not be viewed, in itself, as necessarily encompassing a plurality of items—it will be understood that a set or a subset can encompass only one member or multiple members (unless the context indicates otherwise). It is also to be understood that the term “aggregate” may similarly be used to refer to a group of one as well as a plural group. Thus, for example, if there are one or more items that, in aggregate, include one or more sub-items, this is inclusive of a single item including a single sub-item, a single item including multiple sub-items, multiple items that each include a single sub-item, and multiple items that each include multiple subitems, as well as other permutations and combinations, e.g., hybrids of such examples.

It is understood that the examples and embodiments described herein are for illustrative purposes only and that various modifications or changes in light thereof will be suggested to persons skilled in the art. Although various details have been omitted for clarity's sake, various design alternatives may be implemented. Therefore, the present examples are to be considered as illustrative and not restrictive, and the disclosure is not to be limited to the details given herein, but may be modified within the scope of the disclosure.

It is to be understood that the above disclosure, while focusing on a particular example implementation or implementations, is not limited to only the discussed example, but may also apply to similar variants and mechanisms as well, and such similar variants and mechanisms are also considered to be within the scope of this disclosure.

Similarly, while operations are depicted in the drawings in a particular order, this should not be understood as requiring that such operations be performed in the particular order shown or in sequential order, or that all illustrated operations be performed, to achieve desirable results. Further, the drawings may schematically depict one more example processes in the form of a flow diagram. However, other operations that are not depicted can be incorporated in the example processes that are schematically illustrated. For example, one or more additional operations can be performed before, after, simultaneously, or between any of the illustrated operations. In certain circumstances, multitasking and parallel processing may be advantageous. Moreover, the separation of various system components in the implementations described above should not be understood as requiring such separation in all implementations, and it should be understood that the described program components and systems can generally be integrated together in a single software product or packaged into multiple software products. Additionally, other implementations are within the scope of the following claims. In some cases, the actions recited in the claims can be performed in a different order and still achieve desirable results.

The term “substantially” herein, unless otherwise specified, means within 5% of the referenced value. For example, substantially perpendicular means within +/−5% of parallel. The term “substantially” may be used herein to indicate that while exactness of measurements and relationships may be intended, exactness is not always achieved or achievable because of manufacturing imperfections and tolerances. For instance, it may be intended to manufacture two separate features to have the same size (e.g., two holes), but because of various manufacturing imperfections, these features may be close to, but not exactly, the same size.

1. A substrate support for semiconductor processing, the substrate support comprising:
a base plate with a wafer support area on a top of the base plate, the wafer support area having an outer boundary that extends around a center axis of the base plate and configured to support a wafer; and
an optical wafer edge heating unit having one or more light sources and one or more light emission surfaces, wherein the one or more light emission surfaces:
encircle the outer boundary when viewed along the center axis,
are positioned radially outwards from the outer boundary when viewed along the center axis,
are positioned radially offset below the outer boundary by an offset distance when viewed along an axis perpendicular to the center axis, and
direct light in a direction having a directional component that is parallel to the center axis.

2. The substrate support of claim 1, wherein:
the one or more light sources are a plurality of light emitting diodes, and
each light emission surface is a part of a corresponding light emitting diode.

3. The substrate support of claim 2, wherein the light emitting diodes are vertical-cavity surface-emitting lasers (VCSEL).

4. The substrate support of claim 2, wherein the plurality of light emitting diodes includes less than about 300 light emitting diodes.

5. (canceled)

6. (canceled)

7. The substrate support of claim 1, wherein:
the one or more light sources is a laser emission source, and
each light emission surface is a part of lens connected via fiberoptic cable to the laser emission source.

8-10. (canceled)

11. The substrate support of claim 1, further comprising one or more windows comprising a material transparent to light emitted by the one or more light sources, wherein the one or more windows are:
positioned above the one or more light emission surfaces such that light from the one or more light emission surfaces passes through the one or more windows, and
positioned along the center axis between the wafer support area and the one or more light emission surfaces.

12. The substrate support of claim 11, wherein the substrate support includes a plurality of windows.

13. The substrate support of claim 12, wherein each window corresponds to each one of the one or more light emission surfaces.

14. (canceled)

15. (canceled)

16. The substrate support of claim 1, further comprising an active cooling unit that includes one or more coolant channels and a circumferential cooling fin thermally connected to the one or more coolant channels, wherein the circumferential cooling fin:
extends around the center axis,
is positioned radially inwards from the one or more light emission surfaces, and
is positioned from the outer boundary by a radial distance of less than or equal to 4 mm.

17. The substrate support of claim 16, further comprising a wafer heating unit positioned within the base plate and having one or more heating zones configured to heat a wafer on the wafer support area, wherein:
the one or more light emission surfaces are radially offset from and encircles the one or more heating zones, and
the circumferential cooling fin extends around the one or more heating zones when viewed along the center axis, and is radially interposed between the one or more heating zones and the one or more light emission surfaces when viewed along the center axis.

18. The substrate support of claim 17, further comprising a thermal insulator radially interposed between the circumferential cooling fin and the one or more heating zones.

19. The substrate support of claim 16, wherein the circumferential cooling fin has a radial thickness less than or equal to about 4 mm.

20. The substrate support of claim 16, wherein:
the circumferential cooling fin has a radial thickness that is at least partially defined by an inner radius and an outer radius, and
the inner radius is less than or equal to about 4 mm from the outer boundary of the wafer support area.

21. The substrate support of claim 16, wherein the circumferential cooling fin is thermally connected to the outer boundary of the wafer support area.

22. The substrate support of claim 16, wherein:
the coolant channels are positioned along the center axis between the outer boundary and the one or more light emission surfaces,
the coolant channels are positioned within a portion of the base plate,
one or more ports extend through the portion of the base plate, and
the one or more light emission surfaces are connected to the one or more ports such that light from the one or more light emission surfaces passes through the one or more ports to reach the wafer.

23. The substrate support of claim 16, wherein the one or more light emission surfaces are positioned along the center axis between the outer boundary and the coolant channels.

24. The substrate support of claim 16, further comprising a thermal insulator positioned radially inwards of the circumferential cooling fin and the one or more light emission surfaces.

25-30. (canceled)

31. An apparatus comprising:
a processing chamber defining a chamber interior;
a substrate support including:
a base plate with a wafer support area on a top of the base plate, the wafer support area having an outer boundary that extends around a center axis of the base plate and configured to support a wafer,
an optical wafer edge heating unit having one or more light sources and a one or more light emission surfaces, wherein the one or more light emission surfaces:
encircle the outer boundary when viewed parallel to the center axis,
are positioned radially outwards from the outer boundary when viewed along the center axis,
are positioned radially offset below the outer boundary by an offset distance when viewed along an axis perpendicular to the center axis, and
direct light in at a direction parallel to the center axis, and
a substrate heating unit positioned within the base plate and having one or more heating zones configured to heat a wafer on the wafer support area, wherein the one or more light emission surfaces are radially offset from and encircles the one or more heating zones.

32. The apparatus of claim 31, further comprising a controller with instructions that are configured to:
cause the substrate heating unit to maintain a wafer positioned on the wafer support area at a first temperature, and
cause, while concurrently maintaining the wafer at the first temperature, the optical wafer edge heating unit to maintain an edge region of the wafer at a second temperature higher than the first temperature.

33. The apparatus of claim 31, wherein the first temperature is between about 20° C. and about 120° C., and the second temperature is between about 40° C. and about 150° C.
